(19) United States
(12) Patent Application Publication
(10) Pub. No.: US 2026/0088099 A1
(43) Pub. Date: Mar. 26, 2026

(54) SEMICONDUCTOR MEMORY DEVICE

(71) Applicant: KIOXIA CORPORATION, Tokyo (JP)

(72) Inventor: Yasuhiro SHIINO, Fujisawa Kanagawa (JP)

(73) Assignee: KIOXIA CORPORATION, Tokyo (JP)

(21) Appl. No.: 19/077,116

(22) Filed: Mar. 12, 2025

(30) Foreign Application Priority Data
Sep. 20, 2024 (JP) 2024-163297

(51) Int. Cl. G11C 16/16; G11C 16/10; G11C 16/26

(52) U.S. Cl. CPC G11C 16/16; G11C 16/102; G11C 16/26

(57) ABSTRACT

A semiconductor memory device includes a memory block including first and second sub memory blocks, a bit line and a source line, and a control circuit. The first and the second sub memory blocks include first and second memory cells and first and second word lines, respectively. The control circuit performs, in an erase operation on the memory block, a first determination operation to determine a write state of the second memory cell, a first erase operation performed when the second memory cell is in the write state, and a second erase operation performed when the second memory cell is in an erase state.

### CROSS-REFERENCE TO RELATED APPLICATIONS

This application is based upon and claims the benefit of Japanese Patent Application No. 2024-163297, filed on Sep. 20, 2024, the entire contents of which are incorporated herein by reference.

### BACKGROUND

### Field

Embodiments described herein relate generally to a semiconductor memory device.

### Description of the Related Art

There has been known a semiconductor memory device that includes a substrate, a memory block arranged with the substrate in a first direction intersecting with a surface of the substrate, and a control circuit that controls the memory block.

### BRIEF DESCRIPTION OF THE DRAWINGS

FIG. 1 is a schematic block diagram for describing a semiconductor memory device according to a first embodiment;

FIG. 2 is a schematic side view for describing the semiconductor memory device;

FIG. 3 is a schematic plan view for describing the semiconductor memory device;

FIG. 4 is a schematic block diagram for describing the semiconductor memory device;

FIG. 5 is a schematic circuit diagram for describing the semiconductor memory device;

FIG. 6 is a schematic perspective view for describing the semiconductor memory device;

FIG. 7 is a schematic plan view for describing the semiconductor memory device;

FIG. 8 is a schematic cross-sectional view for describing the semiconductor memory device;

FIG. 9 is a schematic cross-sectional view for describing the semiconductor memory device;

FIG. 10A to FIG. 10C are schematic histograms for describing a threshold voltage of a memory cell MC that stores 3-bit data;

FIG. 11 is a timing chart for describing an operation method of the semiconductor memory device;

FIG. 12 is a schematic cross-sectional view for describing the operation method of the semiconductor memory device;

FIG. 13 is a flowchart for describing the operation method of the semiconductor memory device;

FIG. 14 is a timing chart for describing the operation method of the semiconductor memory device;

FIG. 15 is a schematic cross-sectional view for describing the operation method of the semiconductor memory device;

FIG. 16 is a flowchart for describing the operation method of the semiconductor memory device;

FIG. 17 is a timing chart for describing the operation method of the semiconductor memory device;

FIG. 18 is a schematic cross-sectional view for describing the operation method of the semiconductor memory device;

FIG. 19 is a schematic cross-sectional view for describing the operation method of the semiconductor memory device;

FIG. 20 is a flowchart for describing the operation method of the semiconductor memory device;

FIG. 21 is a schematic diagram illustrating an example of a write status of a sub-block of the semiconductor memory device;

FIG. 22 is a schematic diagram illustrating an example of the write status of the sub-block of the semiconductor memory device;

FIG. 23 is a schematic diagram illustrating an example of the write status of the sub-block of the semiconductor memory device;

FIG. 24 is a timing chart for describing the operation method of the semiconductor memory device;

FIG. 25 is a schematic cross-sectional view for describing the operation method of the semiconductor memory device;

FIG. 26 is a graph for describing the semiconductor memory device;

FIG. 27 is a graph for describing a semiconductor memory device according to a comparative example;

FIG. 28 is a graph for describing the semiconductor memory device according to the first embodiment;

FIG. 29A and FIG. 29B are histograms for describing the semiconductor memory device according to the comparative example;

FIG. 30 is a flowchart for describing an operation method of a semiconductor memory device according to a second embodiment;

FIG. 31 is a schematic diagram illustrating an example of a write status of a sub-block of the semiconductor memory device;

FIG. 32 is a schematic diagram illustrating an example of the write status of the sub-block of the semiconductor memory device;

FIG. 33 is a schematic diagram illustrating an example of the write status of the sub-block of the semiconductor memory device;

FIG. 34 is a schematic diagram illustrating an example of the write status of the sub-block of the semiconductor memory device;

FIG. 35 is a schematic cross-sectional view for describing the operation method of the semiconductor memory device;

FIG. 36 is a schematic cross-sectional view for describing the operation method of the semiconductor memory device;

FIG. 37 is a graph for describing the semiconductor memory device;

FIG. 38 is a graph for describing the semiconductor memory device;

FIG. 39 is a schematic perspective view for describing a semiconductor memory device according to a third embodiment;

FIG. 40 is a flowchart for describing an operation method of the semiconductor memory device;

FIG. 41 is a schematic diagram illustrating an example of a write status of a sub-block of the semiconductor memory device;

FIG. 42 is a schematic diagram illustrating an example of the write status of the sub-block of the semiconductor memory device;

FIG. 43 is a schematic diagram illustrating an example of the write status of the sub-block of the semiconductor memory device;

FIG. 44 is a schematic diagram illustrating an example of the write status of the sub-block of the semiconductor memory device;

FIG. 45 is a flowchart for describing an operation method of a semiconductor memory device according to a fourth embodiment;

FIG. 46 is a schematic diagram illustrating an example of a write status of a sub-block of the semiconductor memory device;

FIG. 47 is a schematic diagram illustrating an example of the write status of the sub-block of the semiconductor memory device;

FIG. 48 is a schematic diagram illustrating an example of the write status of the sub-block of the semiconductor memory device;

FIG. 49 is a schematic diagram illustrating an example of the write status of the sub-block of the semiconductor memory device;

FIG. 50 is a schematic diagram illustrating an example of the write status of the sub-block of the semiconductor memory device;

FIG. 51 is a schematic diagram illustrating an example of the write status of the sub-block of the semiconductor memory device;

FIG. 52 is a schematic histogram for describing a threshold voltage of a memory cell MC that stores 1-bit data;

FIG. 53 is a flowchart for describing an operation method of a semiconductor memory device according to a fifth embodiment;

FIG. 54 is a schematic diagram illustrating an example of a write status of a sub-block of the semiconductor memory device;

FIG. 55 is a schematic diagram illustrating an example of the write status of the sub-block of the semiconductor memory device;

FIG. 56 is a schematic diagram illustrating an example of the write status of the sub-block of the semiconductor memory device; and

FIG. 57 is a schematic diagram illustrating an example of the write status of the sub-block of the semiconductor memory device.

### DETAILED DESCRIPTION

A semiconductor memory device according to one embodiment comprises: a substrate; a memory block including a first sub memory block and a second sub memory block arranged in a first direction intersecting with a surface of the substrate; a bit line disposed on one side in the first direction with respect to the memory block; a source line disposed on the other side in the first direction with respect to the memory block; and a control circuit that controls the memory block. The first sub memory block includes: a first memory cell electrically connected to the bit line and the source line; and a first word line electrically connected to the first memory cell. The second sub memory block includes: a second memory cell electrically connected to the bit line and the source line; and a second word line electrically connected to the second memory cell. The control circuit is configured to be able to perform, in an erase operation on the memory block: a first determination operation to determine whether or not the second memory cell is in a write state; a first erase operation performed when the second memory cell is in the write state; and a second erase operation performed when the second memory cell is in an erase state. In the first erase operation, an erase voltage is applied to one or both of the bit line and the source line, and a select erase voltage lower than the erase voltage is applied to the first word line and the second word line. In the second erase operation, the erase voltage is applied to one or both of the bit line and the source line, the select erase voltage is applied to the first word line, and an unselect erase voltage lower than the erase voltage and higher than the select erase voltage is applied to the second word line.

Next, the semiconductor memory devices according to embodiments are described in detail with reference to the drawings. The following embodiments are only examples, and not described for the purpose of limiting the present invention.

In this specification, when referring to a “semiconductor memory device”, it may mean a memory die (memory chip) and may mean a memory system including a controller die, such as a memory card and a Solid State Drive (SSD). Further, it may mean a configuration including a host computer, such as a smartphone, a tablet terminal, and a personal computer.

In this specification, when it is referred that a first configuration “is electrically connected” to a second configuration, the first configuration may be directly connected to the second configuration, and the first configuration may be connected to the second configuration via a wiring, a semiconductor member, a transistor, or the like. For example, when three transistors are connected in series, even when the second transistor is in an OFF state, the first transistor is “electrically connected” to the third transistor.

In this specification, when it is referred that the first configuration “is connected between” the second configuration and a third configuration, it may mean that the first configuration, the second configuration, and the third configuration are connected in series and the second configuration is connected to the third configuration via the first configuration.

In this specification, when it is referred that a circuit or the like “electrically conducts” two wirings or the like, it may mean, for example, that this circuit or the like includes a transistor or the like, this transistor or the like is disposed in a current path between the two wirings, and this transistor or the like enters an ON state.

### First Embodiment

### [Memory System 10]

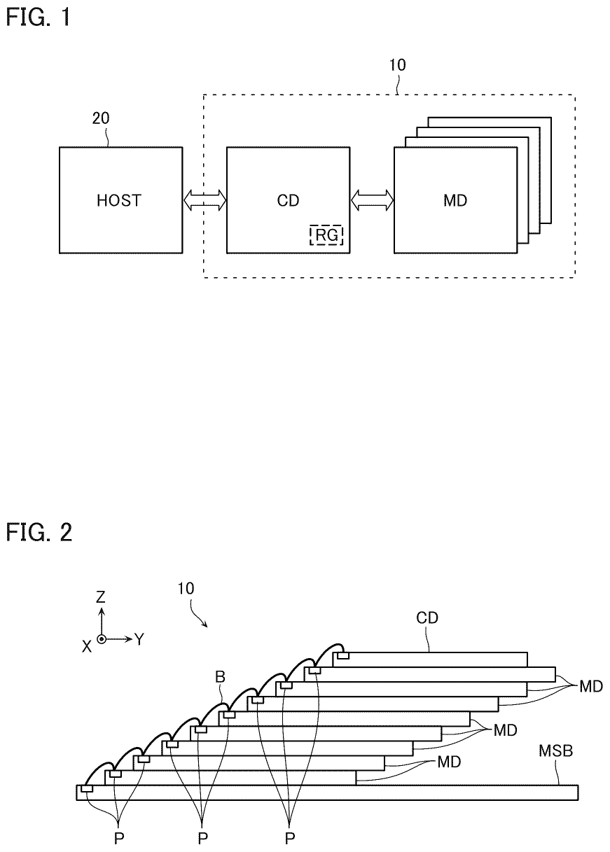

FIG. 1 is a schematic block diagram illustrating a configuration of a memory system 10 according to the first embodiment.

The memory system 10, for example, reads, writes, and erases user data according to a signal transmitted from a host computer 20. The memory system 10 is, for example, any system that can store user data including a memory card and an SSD. The memory system 10 includes a plurality of memory dies MD that store the user data and a controller die CD connected to these plurality of memory dies MD and the host computer 20. The controller die CD includes, for example, a processor, a RAM, and the like, and performs conversion between a logical address and a physical address, bit error detection/correction, a garbage collection (compaction), a wear leveling, and the like. The controller die CD may include, for example, a register RG. The register RG may be configured to hold information on a state of the memory die MD, for example, information on an erase state and a write state in a unit of sub-block described later.

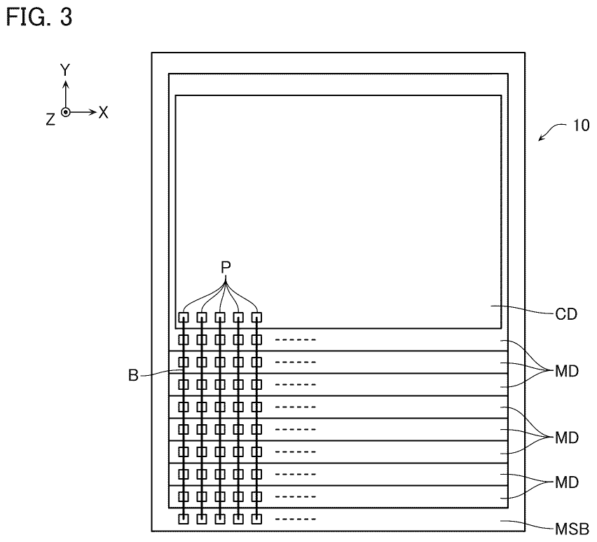

FIG. 2 is a schematic side view illustrating an exemplary configuration of the memory system 10 according to the embodiment. FIG. 3 is a schematic plan view illustrating the exemplary configuration. For convenience of description, FIG. 2 and FIG. 3 omit a part of the configuration.

As illustrated in FIG. 2, the memory system 10 according to the embodiment includes a mounting substrate MSB, the plurality of memory dies MD stacked on the mounting substrate MSB, and the controller die CD stacked on the memory dies MD. On an upper surface of the mounting substrate MSB, a pad electrode P is disposed in a region at an end portion in a Y-direction, and a part of the other region is bonded to a lower surface of the memory die MD via an adhesive and the like. On an upper surface of the memory die MD, the pad electrode P is disposed in a region at an end portion in the Y-direction, and the other region is bonded to a lower surface of another memory die MD or the controller die CD via the adhesive and the like. On an upper surface of the controller die CD, the pad electrode P is disposed in a region at an end portion in the Y-direction.

As illustrated in FIG. 3, the mounting substrate MSB, the plurality of memory dies MD, and the controller die CD each include a plurality of the pad electrodes P arranged in an X-direction. The plurality of pad electrodes P disposed on each of the mounting substrate MSB, the plurality of memory dies MD, and the controller die CD are mutually connected via bonding wires B.

Note that the configurations illustrated in FIG. 2 and FIG. 3 are merely examples, and specific configurations are appropriately adjustable. For example, in the example illustrated in FIG. 2 and FIG. 3, the controller die CD is stacked on the plurality of memory dies MD, and these configurations are connected with the bonding wires B. In such a configuration, the plurality of memory dies MD and the controller die CD are included in one package. However, the controller die CD may be included in a package different from the memory die MD. Additionally, the plurality of memory dies MD and the controller die CD may be connected to one another via through electrodes or the like, not the bonding wires B.

### [Configuration of Memory Die MD]

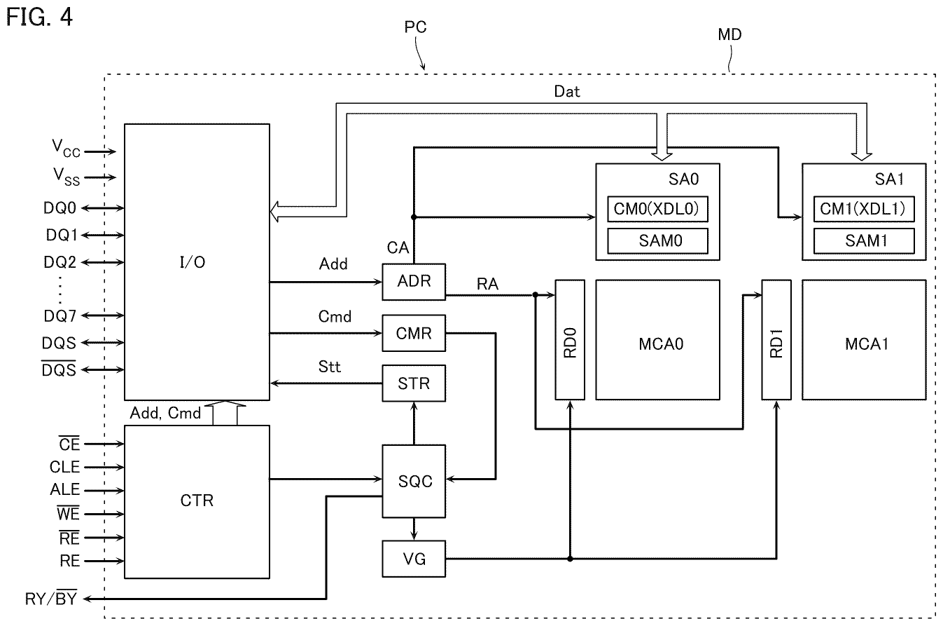

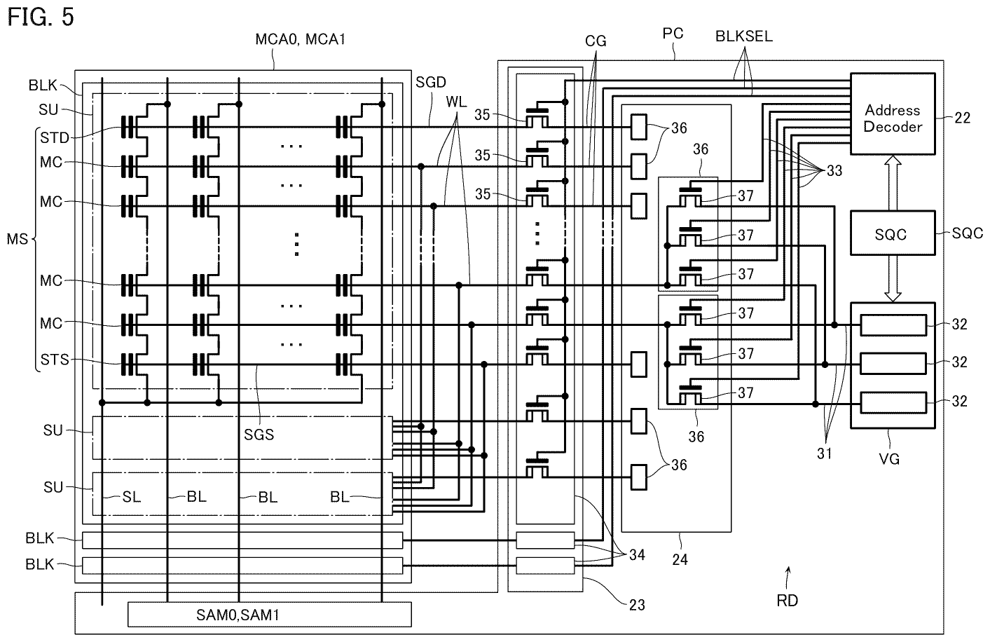

FIG. 4 is a schematic block diagram illustrating a configuration of the memory die MD according to the first embodiment. FIG. 5 is a schematic circuit diagram illustrating a configuration of a part of the memory die MD. For convenience of description, FIG. 4 and FIG. 5 omit a part of the configuration.

FIG. 4 illustrates a plurality of control terminals and the like. These plurality of control terminals are represented as control terminals corresponding to a high active signal (positive logic signal) in some cases, represented as control terminals corresponding to a low active signal (negative logic signal) in some cases, and represented as control terminals corresponding to both the high active signal and the low active signal in some cases. In FIG. 4, a reference sign of the control terminal corresponding to the low active signal includes an over line (overbar). In this specification, a reference sign of the control terminal corresponding to the low active signal includes a slash (“/”). The description of FIG. 4 is an example, and specific aspects are appropriately adjustable. For example, a part of or all of the high active signals can be changed to the low active signals, or a part of or all of the low active signals can be changed to the high active signals.

As illustrated in FIG. 4, the memory die MD includes memory cell arrays MCA0, MCA1 storing the user data, and a peripheral circuit PC connected to the memory cell arrays MCA0, MCA1. In the following description, the memory cell arrays MCA0, MCA1 are referred to as a memory cell array MCA in some cases.

### [Circuit Configuration of Memory Cell Array MCA]

As illustrated in FIG. 5, the memory cell array MCA includes a plurality of memory blocks BLK. These plurality of memory blocks BLK each include a plurality of string units SU. These plurality of string units SU each include a plurality of memory strings MS. These plurality of memory strings MS have one ends each connected to the peripheral circuit PC via a bit line BL. Furthermore, these plurality of memory strings MS have other ends each connected to the peripheral circuit PC via a common source line SL.

The memory string MS includes a drain-side select transistor STD, a plurality of memory cells MC (memory cell transistors), a source-side select transistor STS, which are connected in series between the bit line BL and the source line SL. Hereinafter, the drain-side select transistor STD and the source-side select transistor STS may be simply referred to as select transistors (STD, STS).

The memory cell MC is a field-effect type transistor including a semiconductor layer, a gate insulating film, and a gate electrode. The semiconductor layer functions as a channel region. The gate insulating film includes an electric charge accumulating film. The memory cell MC has a threshold voltage that changes according to an electric charge amount in the electric charge accumulating film. The memory cell MC stores one bit or a plurality of bits of user data. Word lines WL are connected to the respective gate electrodes of the plurality of memory cells MC corresponding to one memory string MS. These respective word lines WL are connected to all of the memory strings MS in one memory block BLK in common.

The select transistors (STD, STS) are field-effect type transistors each including a semiconductor layer, a gate insulating film, and a gate electrode. The semiconductor layer functions as a channel region. A drain-side select gate line SGD and a source-side select gate line SGS are connected to the gate electrodes of the select transistors (STD, STS), respectively. The drain-side select gate line SGD is disposed corresponding to the string unit SU and connected to all of the memory strings MS in one string unit SU in common. The source-side select gate line SGS is connected to all of the memory strings MS in the memory block BLK in common. Hereinafter, the drain-side select gate line SGD and the source-side select gate line SGS may be simply referred to as select gate lines (SGD, SGS).

### [Circuit Configuration of Peripheral Circuit PC]

For example, as illustrated in FIG. 4, the peripheral circuit PC includes row decoders RD0, RD1 and sense amplifiers SA0, SA1 connected to the memory cell arrays MCA0, MCA1, respectively. The peripheral circuit PC includes a voltage generation circuit VG and a sequencer SQC. The peripheral circuit PC includes an input/output control circuit I/O, a logic circuit CTR, an address register ADR, a command register CMR, and a status register STR. In the following description, the row decoders RD0, RD1 may be referred to as a row decoder RD, and the sense amplifiers SA0, SA1 may be referred to as a sense amplifier SA.

For example, as illustrated in FIG. 5, the row decoder RD (FIG. 4) includes an address decoder 22 decoding address data Add (FIG. 4). Further, the row decoder RD (FIG. 4) includes a block select circuit 23 and a voltage select circuit 24 that transfer an operating voltage to the memory cell array MCA according to an output signal of the address decoder 22.

The address decoder 22 is connected to a plurality of block select lines BLKSEL and a plurality of voltage select lines 33. For example, the address decoder 22 sequentially refers to a row address RA in the address register ADR (FIG. 4) in response to a control signal from the sequencer SQC.

The block select circuit 23 includes a plurality of block selectors 34 corresponding to the memory blocks BLK. Each of the block selectors 34 includes a plurality of block select transistors 35 corresponding to the word lines WL and the select gate lines (SGD, SGS). The block select transistor 35 is, for example, a field-effect type high breakdown voltage transistor. The block select transistors 35 have drain electrodes each electrically connected to the corresponding word line WL or select gate lines (SGD, SGS). The block select transistors 35 have source electrodes each electrically connected to a voltage supply line 31 via a wiring CG and the voltage select circuit 24. The block select transistors 35 have gate electrodes connected to the corresponding block select line BLKSEL in common.

The voltage select circuit 24 includes a plurality of voltage selectors 36 corresponding to the word lines WL and the select gate lines (SGD, SGS). These plurality of voltage selectors 36 each include a plurality of voltage select transistors 37. The voltage select transistor 37 is, for example, a field-effect type high breakdown voltage transistor. The voltage select transistors 37 have drain terminals each electrically connected to the corresponding word line WL or select gate lines (SGD, SGS) via the wiring CG and the block select circuit 23. Source terminals are each electrically connected to the corresponding voltage supply line 31. The gate electrodes are each connected to the corresponding voltage select line 33.

The sense amplifiers SA0, SA1 (FIG. 4) include sense amplifier modules SAM0, SAM1 and cache memories CM0, CM1 (data registers), respectively. The cache memories CM0, CM1 include latch circuits XDL0, XDL1, respectively. In the following description, the sense amplifier modules SAM0, SAM1 may be referred to as a sense amplifier module SAM, the cache memories CM0, CM1 may be referred to as a cache memory CM, and the latch circuits XDL0, XDL1 may be referred to as a latch circuit XDL.

For example, the sense amplifier module SAM includes sense circuits corresponding to the respective plurality of bit lines BL, a plurality of latch circuits connected to the sense circuits, and the like.

The cache memory CM includes a plurality of the latch circuits XDL. The respective plurality of latch circuits XDL are connected to the latch circuits inside the sense amplifier module SAM. In the latch circuit XDL, for example, user data written into the memory cell MC or user data read out from the memory cell MC is stored.

For example, a column decoder is connected to the cache memory CM. The column decoder decodes a column address CA stored in the address register ADR (FIG. 4) and selects the latch circuit XDL corresponding to the column address CA.

User data Dat included in these plurality of latch circuits XDL are sequentially transferred to the latch circuits inside the sense amplifier modules SAM in the write operation. The user data Dat included in the latch circuits inside the sense amplifier modules SAM are sequentially transferred to the latch circuits XDL in the read operation. The user data Dat included in the latch circuits XDL are sequentially transferred to the input/output control circuit I/O in a data-out operation.

For example, as illustrated in FIG. 5, the voltage generation circuit VG (FIG. 4) is connected to the plurality of voltage supply lines 31. The voltage generation circuit VG includes, for example, a step down circuit, such as a regulator, and a step up circuit, such as a charge pump circuit 32. These step down circuit and step up circuit are each connected to a voltage supply line to which a power supply voltage V_{CC} and a ground voltage V_{SS} (FIG. 4) are applied. These voltage supply lines are connected to, for example, the pad electrodes P described with reference to FIG. 2 and FIG. 3. For example, the voltage generation circuit VG generates a plurality of operating voltages applied to the bit line BL, the source line SL, the word line WL, and the select gate lines (SGD, SGS) in the read operation, the write operation, and the erase operation on the memory cell array MCA, in accordance with the control signal from the sequencer SQC, and simultaneously outputs the operating voltages to the plurality of voltage supply lines 31. The operating voltage output from the voltage supply line 31 is appropriately adjusted in accordance with the control signal from the sequencer SQC.

In accordance with command data Cmd stored in the command register CMR, the sequencer SQC (FIG. 4) outputs an internal control signal to the row decoders RD0, RD1, the sense amplifier modules SAM0, SAM1, and the voltage generation circuit VG. The sequencer SQC outputs status data Stt indicating the state of the memory die MD to the status register STR as appropriate.

The sequencer SQC generates a ready/busy signal and outputs the ready/busy signal to a terminal RY/(/BY). In a period where the terminal RY/(/BY) is in an “L” state (busy period), an access to the memory die MD is basically inhibited. In a period where the terminal RY/(/BY) is in an “H” state (ready period), the access to the memory die MD is permitted. The terminal RY/(/BY) is achieved by, for example, the pad electrode P described with reference to FIG. 2 and FIG. 3.

As illustrated in FIG. 4, the address register ADR is connected to the input/output control circuit I/O and stores the address data Add input from the input/output control circuit I/O. For example, the address register ADR includes a plurality of 8-bit register strings. For example, when an internal operation, such as the read operation, the write operation, or the erase operation, is performed, the register string latches the address data Add corresponding to the internal operation in execution.

The address data Add, for example, includes a column address CA (FIG. 4) and a row address RA (FIG. 4). For example, the row address RA includes a block address to identify the memory block BLK (FIG. 5), a page address to identify the string unit SU and the word line WL, a plane address to identify the memory cell array MCA (plane), and a chip address to identify the memory die MD.

The command register CMR is connected to the input/output control circuit I/O and stores the command data Cmd input from the input/output control circuit I/O. For example, the command register CMR includes at least one set of an 8-bit register string. When the command data Cmd is stored in the command register CMR, the control signal is transmitted to the sequencer SQC.

The status register STR is connected to the input/output control circuit I/O and stores the status data Stt output to the input/output control circuit I/O. For example, the status register STR includes a plurality of 8-bit register strings. For example, when the internal operation, such as the read operation, the write operation, or the erase operation, is performed, the register string latches the status data Stt regarding the internal operation in execution. The register string, for example, latches ready/busy information of the memory cell arrays MCA0, MCA1.

The input/output control circuit I/O (FIG. 4) includes data signal input/output terminals DQ0 to DQ7, data strobe signal input/output terminals DQS, /DQS, a shift register, and a buffer circuit.

Each of the data signal input/output terminals DQ0 to DQ7 and the data strobe signal input/output terminals DQS, /DQS is achieved by, for example, the pad electrode P described with reference to FIG. 2 and FIG. 3. Data input via the data signal input/output terminals DQ0 to DQ7 are input from the buffer circuit to the cache memory CM, the address register ADR, or the command register CMR in response to the internal control signal from the logic circuit CTR. Data output via the data signal input/output terminals DQ0 to DQ7 are input to the buffer circuit from the cache memory CM or the status register STR in response to the internal control signal from the logic circuit CTR.

Signals input via the data strobe signal input/output terminals DQS, /DQS (for example, a data strobe signal and its complementary signal) are used at data input via the data signal input/output terminals DQ0 to DQ7. The data input via the data signal input/output terminals DQ0 to DQ7 are taken in the shift register in the input/output control circuit I/O at a timing of a voltage rising edge (switching of the input signal) of the data strobe signal input/output terminal DQS and a voltage falling edge (switching of the input signal) of the data strobe signal input/output terminal/DQS, and at a timing of a voltage falling edge (switching of the input signal) of the data strobe signal input/output terminal DQS and a voltage rising edge (switching of the input signal) of the data strobe signal input/output terminal/DQS.

The logic circuit CTR (FIG. 4) includes a plurality of external control terminals /CE, CLE, ALE, /WE, /RE, RE and a logic circuit connected to these plurality of external control terminals /CE, CLE, ALE, /WE, /RE, RE. The logic circuit CTR receives an external control signal from the controller die CD via the external control terminals /CE, CLE, ALE, /WE, /RE, RE and outputs the internal control signal to the input/output control circuit I/O in response to the external control signal.

Note that, for example, each of the external control terminals /CE, CLE, ALE, /WE, /RE, RE is achieved by the pad electrode P described with reference to FIG. 2 and FIG. 3.

### [Structure of Memory Die MD]

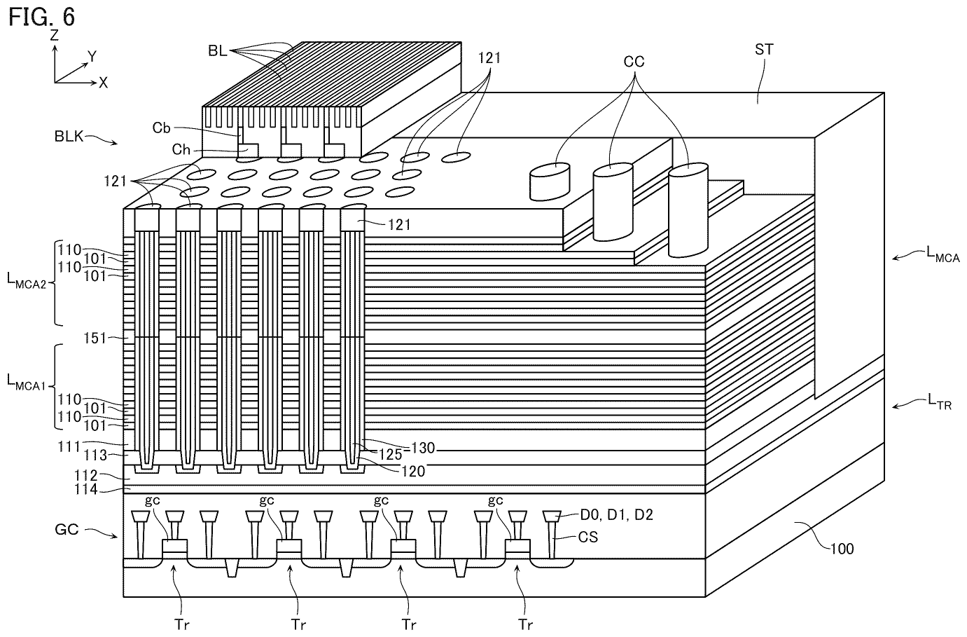

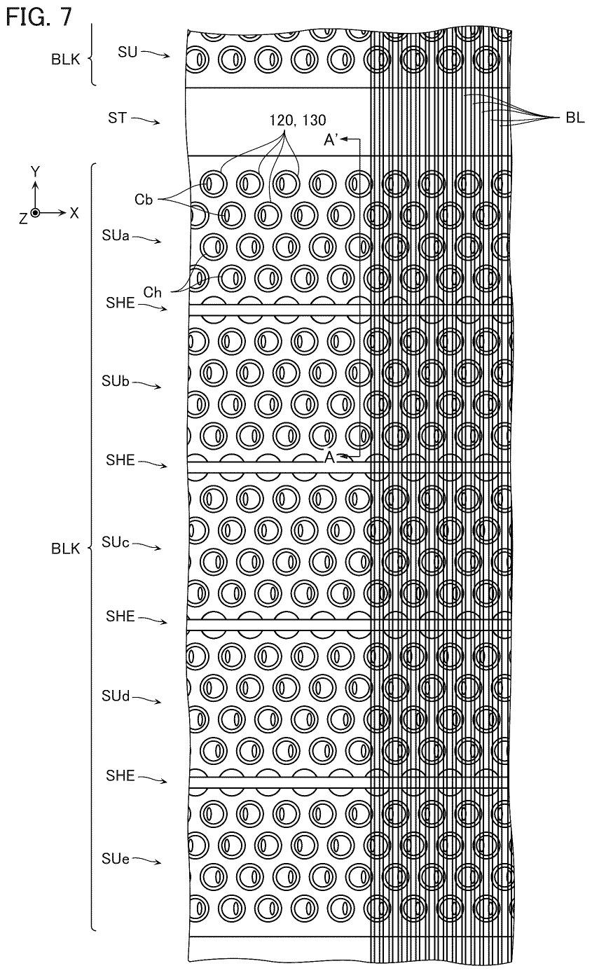

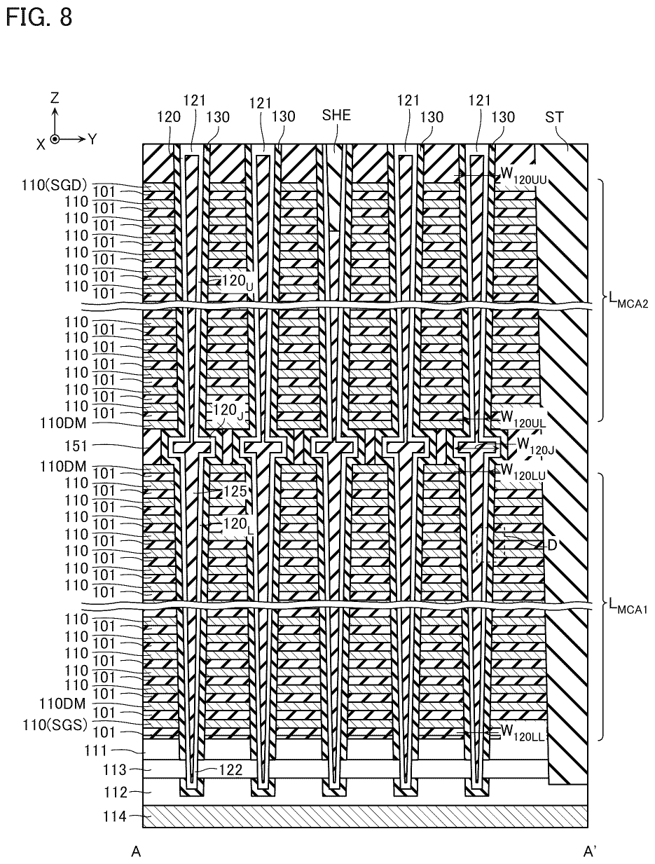

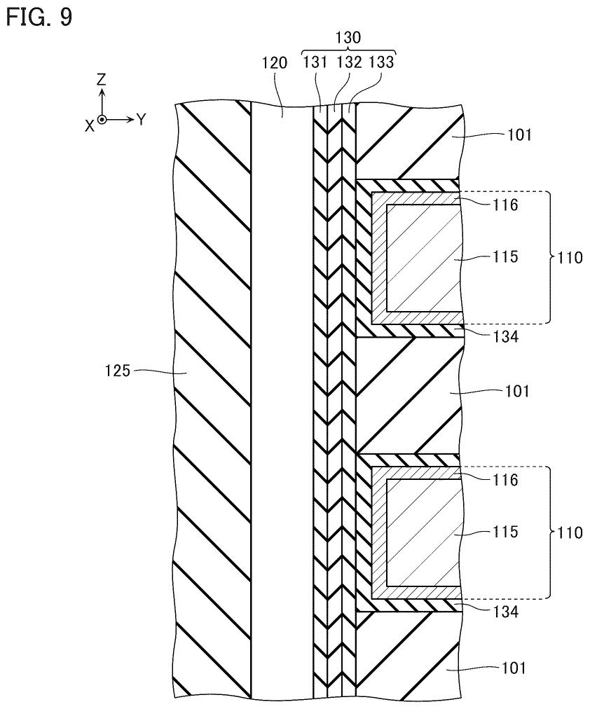

FIG. 6 is a schematic perspective view illustrating the configuration of a part of the memory die MD. FIG. 7 is a schematic plan view illustrating the configuration of a part of the memory die MD. FIG. 8 and FIG. 9 are schematic cross-sectional views illustrating the configuration of a part of the memory die MD. FIG. 8 is a schematic cross-sectional view illustrating the structure illustrated in FIG. 7 taken along the line A-A′ when viewed in the arrow direction. FIG. 9 is a schematic cross-sectional view illustrating an enlarged region D illustrated in FIG. 8. For convenience of explanation, FIG. 6 to FIG. 9 omit a part of the configuration.

For example, as illustrated in FIG. 6, the semiconductor memory device according to the embodiment includes a transistor layer LTR disposed above a semiconductor substrate 100 and a memory cell array layer L_{MCA} disposed above the transistor layer LTR.

A wiring layer GC is disposed on an upper surface of the semiconductor substrate 100 via an insulating layer. The wiring layer GC includes a plurality of electrodes gc opposed to the surface of the semiconductor substrate 100. The regions of the semiconductor substrate 100 and the plurality of electrodes gc included in the wiring layer GC are each connected to a contact CS.

The respective plurality of electrodes gc are opposed to the surface of the semiconductor substrate 100 and function as gate electrodes of a plurality of transistors Tr, electrodes of a plurality of capacitors, and the like constituting the peripheral circuit PC.

The plurality of contacts CS extend in the Z-direction and are connected to the semiconductor substrate 100 or the upper surfaces of the electrodes gc at lower ends. In a connection part between the contact CS and the semiconductor substrate 100, an impurity region containing N-type impurities or P-type impurities is disposed. For example, the contact CS may include a stacked film including a barrier conductive film of titanium nitride (TiN) or the like and a metal film of tungsten (W) or the like.

Each of wiring layers D0, D1, D2 includes a plurality of wirings electrically connected to at least one of the configurations in the memory cell array MCA or the configurations in the peripheral circuit PC. For example, these plurality of wirings may include a stacked film including a barrier conductive film of titanium nitride (TiN) or the like and a metal film of tungsten (W) or the like.

For example, as illustrated in FIG. 6, the memory cell array layer L_{MCA} includes a memory block BLK.

In the example of FIG. 7, the memory block BLK includes five string units SUa to SUe disposed from one side in the Y-direction (the Y-direction positive side in FIG. 7) to the other side in the Y-direction (the Y-direction negative side in FIG. 7). Each of these plurality of string units SUa to SUe corresponds to the string unit SU described with reference to FIG. 5. Between two string units SU adjacent in the Y-direction, the inter-string unit insulating layer SHE of, for example, silicon oxide (SiO₂) is disposed. Between two memory blocks BLK adjacent in the Y-direction, an inter-block structure ST is disposed.

As illustrated in FIG. 6 and FIG. 8, in the memory cell array layer L_{MCA}, the memory block BLK includes a memory cell array layer L_{MCA1} and a memory cell array layer L_{MCA2} disposed above the memory cell array layer L_{MCA1}. Between the memory cell array layer L_{MCA1} and the memory cell array layer L_{MCA2}, an insulating layer 151 of silicon oxide (SiO₂) or the like is disposed. The memory cell array layer L_{MCA1} and the memory cell array layer L_{MCA2} include a plurality of conductive layers 110 arranged in the Z-direction, a plurality of semiconductor layers 120 extending in the Z-direction, and a plurality of gate insulating films 130 each disposed between the plurality of conductive layers 110 and the plurality of semiconductor layers 120.

The conductive layer 110 is an approximately plate-shaped conductive layer extending in the X-direction. As illustrated in FIG. 9, the conductive layer 110 may include a stacked film including a barrier conductive film 116 of titanium nitride (TiN) or the like and a metal film 115 of tungsten (W) or the like. Note that an insulating metal oxide film 134 of alumina (AlO) or the like may be disposed at an upper surface, a lower surface, and a surface opposed to the semiconductor layer 120 of the conductive layer 110. Additionally, for example, the conductive layer 110 may contain polycrystalline silicon containing impurities, such as phosphorus (P) or boron (B), or the like. Respective contacts CC (FIG. 6) are disposed on end portions in the X-direction of the plurality of conductive layers 110. Between the plurality of conductive layers 110 arranged in the Z-direction, an insulating layer 101 of silicon oxide (SiO₂) or the like is disposed.

As illustrated in FIG. 8, a semiconductor layer 111, a semiconductor layer 113, and a semiconductor layer 112 are disposed below the plurality of conductive layers 110 via the insulating layer 101. Between the semiconductor layer 111, the semiconductor layer 112 and the semiconductor layer 120, a part of the gate insulating film 130 is disposed. The semiconductor layer 113 is connected to lower end portions of the semiconductor layers 120.

The semiconductor layer 113 has an upper surface connected to the semiconductor layer 111, and a lower surface connected to the semiconductor layer 112. A conductive layer 114 may be disposed on a lower surface of the semiconductor layer 112. The semiconductor layer 111, the semiconductor layer 113, the semiconductor layer 112, and the conductive layer 114 function as the source lines SL (FIG. 5). For example, the source line SL is disposed for a plurality of memory blocks BLK in common. For example, the semiconductor layer 111, the semiconductor layer 113, and the semiconductor layer 112 contain polycrystalline silicon containing impurities, such as phosphorus (P) or boron (B), or the like. For example, the conductive layer 114 may contain a metal, such as tungsten (W), a conductive layer of tungsten silicide or the like, or another conductive layer.

Among the plurality of conductive layers 110 disposed in the memory cell array layer L_{MCA1}, one or a plurality of conductive layers 110 positioned at the lowermost layers function as the source-side select gate line SGS (FIG. 5) and gate electrodes of a plurality of the source-side select transistors STS (FIG. 5) connected to the source-side select gate line SGS. This conductive layer 110 is electrically independent for each memory block BLK.

Among the plurality of conductive layers 110 disposed in the memory cell array layer L_{MCA1}, one or a plurality of conductive layers 110 positioned above these conductive layers 110 are disposed as dummies. Hereinafter, such a conductive layer 110 is referred to as a dummy conductive layer 110DM. The dummy conductive layer 110DM does not function as the select gate lines (SGD, SGS) or the word line WL. Between the dummy conductive layer 110DM and the semiconductor layer 120, the memory cell MC that stores data is not disposed. Hereinafter, such a dummy conductive layer 110DM may be referred to as a dummy word line DWL.

Among the plurality of conductive layers 110 disposed in the memory cell array layer L_{MCA1}, a plurality of conductive layers 110 positioned above these conductive layers 110 function as the word lines WL (FIG. 5) and the gate electrodes of the plurality of memory cells MC (FIG. 5) connected to the word lines WL. Between these conductive layers 110 and the semiconductor layer 120, the memory cells MC used for storing data are disposed. These plurality of conductive layers 110 are electrically independent for each memory block BLK.

Among the plurality of conductive layers 110 disposed in the memory cell array layer L_{MCA1}, one or a plurality of conductive layers 110 positioned at the uppermost layers are dummy conductive layers 110DM.

Among the plurality of conductive layers 110 disposed in the memory cell array layer L_{MCA2}, one or a plurality of conductive layers 110 positioned at the lowermost layers are dummy conductive layers 110DM.

Among the plurality of conductive layers 110 disposed in the memory cell array layer L_{MCA2}, a plurality of conductive layers 110 positioned above these conductive layers 110 function as the word lines WL (FIG. 5) and the gate electrodes of the plurality of memory cells MC (FIG. 5) connected to the word lines WL. Between these conductive layers 110 and the semiconductor layer 120, the memory cells MC used for storing data are disposed. These plurality of conductive layers 110 are electrically independent for each memory block BLK.

One or a plurality of conductive layers 110 positioned above these conductive layers 110 function as the drain-side select gate line SGD (FIG. 5) and the gate electrodes of the plurality of drain-side select transistors STD (FIG. 5) connected to the drain-side select gate line SGD. These plurality of conductive layers 110 have a width in the Y-direction smaller than that of other conductive layers 110. Between two conductive layers 110 adjacent in the Y-direction, an inter-string unit insulating layer SHE is disposed. These plurality of conductive layers 110 are electrically independent for each string unit SU.

For example, as illustrated in FIG. 6 and FIG. 7, the semiconductor layers 120 are arranged in a predetermined pattern in the X-direction and the Y-direction. The semiconductor layers 120 function as channel regions of the plurality of memory cells MC and the select transistors (STD, STS) included in one memory string MS (FIG. 5). The semiconductor layer 120 includes polycrystalline silicon (Si) or the like. The semiconductor layer 120 has, for example, as illustrated in FIG. 8, an approximately closed-bottomed cylindrical shape and includes an insulating layer 125 of silicon oxide (SiO₂) or the like at its center part.

As illustrated in FIG. 8, the semiconductor layer 120 includes a semiconductor region 120_{L} included in the memory cell array layer L_{MCA1} and a semiconductor region 120_{U} included in the memory cell array layer L_{MCA2}. The semiconductor layer 120 includes a semiconductor region 120 connected to an upper end of the semiconductor region 120_{L} and a lower end of the semiconductor region 120_{U}, an impurity region 122 connected to a lower end of the semiconductor region 120_{L}, and an impurity region 121 connected to an upper end of the semiconductor region 120_{U}.

The semiconductor region 120_{L} is an approximately cylindrical-shaped region extending in the Z-direction. Each of the semiconductor regions 120 has an outer peripheral surface surrounded by the plurality of conductive layers 110 included in the memory cell array layer L_{MCA1} and is opposed to these plurality of conductive layers 110.

The semiconductor region 120_{U} is an approximately cylindrical-shaped region extending in the Z-direction. Each of the semiconductor regions 120_{U} has an outer peripheral surface surrounded by the plurality of conductive layers 110 included in the memory cell array layer L_{MCA2} and is opposed to these plurality of conductive layers 110.

The semiconductor region 120j is disposed above the plurality of conductive layers 110 included in the memory cell array layer L_{MCA1} and disposed below the plurality of conductive layers 110 included in the memory cell array layer L_{MCA2}.

The impurity region 122 is connected to the semiconductor layer 113. The impurity region 122, for example, contains N-type impurities, such as phosphorus (P), or P-type impurities, such as boron (B). In the semiconductor layer 120, the part positioned immediately above the impurity region 122 functions as the channel region of the source-side select transistor STS.

The impurity region 121, for example, contains N-type impurities, such as phosphorus (P). The impurity region 121 is connected to the bit lines BL via a contact Ch and a contact Cb (FIG. 6).

The gate insulating film 130 has an approximately closed-bottomed cylindrical shape covering the outer peripheral surface of the semiconductor layer 120. For example, as illustrated in FIG. 9, the gate insulating film 130 includes a tunnel insulating film 131, an electric charge accumulating film 132, and a block insulating film 133 that are stacked between the semiconductor layer 120 and the conductive layers 110. The tunnel insulating film 131 and the block insulating film 133 are, for example, insulating films of silicon oxide (SiO₂) or the like. The electric charge accumulating film 132 is, for example, silicon nitride (SiN) or the like and is a film that can accumulate electric charge. The tunnel insulating film 131, the electric charge accumulating film 132, and the block insulating film 133 have approximately cylindrical shapes, and extend in the Z-direction along the outer peripheral surface of the semiconductor layer 120.

Note that the gate insulating film 130, for example, may include a floating gate of polycrystalline silicon or the like containing N-type or P-type impurities.

The inter-block structure ST is a structure body that extends in the Z-direction and the X-direction, separates the plurality of insulating layers 101, the plurality of conductive layers 110, the semiconductor layer 111, and the semiconductor layer 113 in the Y-direction, and reaches the semiconductor layer 112. The inter-block structure ST is, for example, an insulating layer of, for example, silicon oxide (SiO₂). Note that the inter-block structure ST may include a conductive layer of, for example, tungsten extending in the X-direction and the Z-direction at the center in the Y-direction, and a lower end of this conductive layer may be connected to the semiconductor layer 112.

[Widths in Radial Directions of Semiconductor Regions 120_{L}, 120_{U}, 120_{J}]

Next, the widths in the radial directions of the semiconductor regions 120_{L}, 120_{U}, 120_{J} are described. Hereinafter, in this specification, a width of the semiconductor layer in an XY cross-sectional surface intersecting with the Z-direction as an extending direction of the semiconductor regions 120_{L}, 120_{U} are referred to as a width in the radial direction. Note that, for sake of convenience of explanation, FIG. 8 or the like illustrates the width in the Y-direction as the width in the radial direction.

A width W_{120LL} in the radial direction of a lower end portion of the semiconductor region 120_{L} (for example, a part positioned below the plurality of conductive layers 110 included in the memory cell array layer L_{MCA1}) is smaller than a width W_{120LU} in the radial direction of an upper end portion of the semiconductor region 120_{L} (for example, a part positioned above the plurality of conductive layers 110 included in the memory cell array layer L_{MCA1}). That is, the width in the radial direction of the semiconductor region 120_{L} becomes small as it goes to the lower side close to the substrate.

A width W_{120UL} in the radial direction of a lower end portion of the semiconductor region 120_{U} (for example, a part positioned below the plurality of conductive layers 110 included in the memory cell array layer L_{MCA2}) is smaller than a width W_{120UU} in the radial direction of an upper end portion of the semiconductor region 120_{U} (for example, a part positioned above the plurality of conductive layers 110 included in the memory cell array layer L_{MCA2}). That is, the width in the radial direction of the semiconductor region 120_{U} decreases toward a lower side close to the substrate and the semiconductor region 120_{J}, and the width in the radial direction is the smallest in the vicinity immediately above the semiconductor region 120_{J}. Note that the width W_{120UL} is smaller than the width W_{120LU}.

A width W_{120J} in the radial direction of the semiconductor region 120j is larger than any of the widths W_{120LL}, W_{120LU}, W_{120UL}, W_{120UU} in the radial direction of the semiconductor regions 120_{L}, 120_{U}.

### [Threshold Voltage of Memory Cell MC Storing a Plurality of Bits]

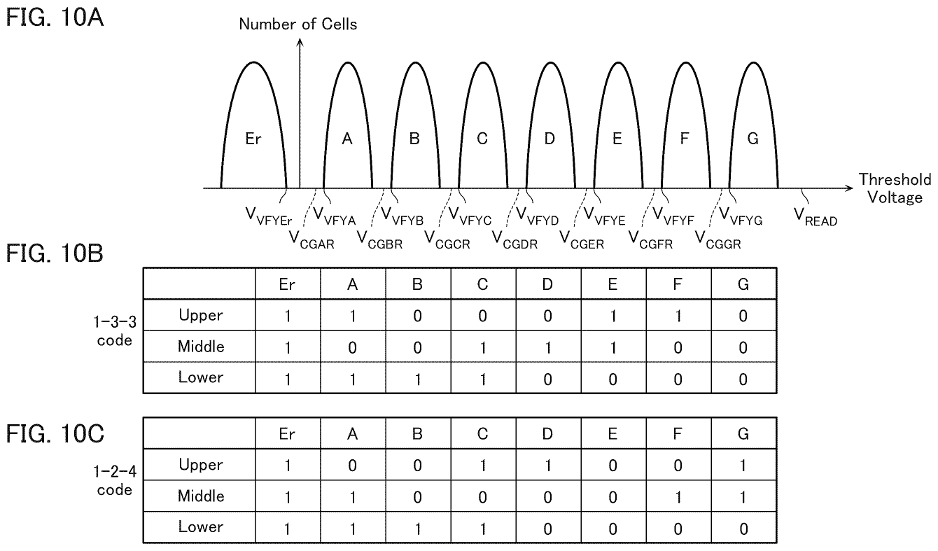

Next, with reference to FIG. 10A, FIG. 10B, and FIG. 10C, the threshold voltage of the memory cell MC storing data of a plurality of bits is described. FIG. 10A, FIG. 10B, and FIG. 10C illustrate the threshold voltage of the memory cell MC storing 3-bit data as an example.

FIG. 10A is a schematic histogram for describing the threshold voltage of the memory cell MC storing the 3-bit data. The horizontal axis indicates the voltage of the word line WL, and the vertical axis indicates the numbers of memory cells MC. FIG. 10B is a table showing an example of a relation between the threshold voltage of the memory cell MC storing the 3-bit data and the stored data. FIG. 10C is a table showing another example of the relation between the threshold voltage of the memory cell MC storing the 3-bit data and the stored data.

In the example of FIG. 10A, the threshold voltages of the memory cells MC are controlled in eight states. The threshold voltage of the memory cell MC controlled in a state Er is smaller than an erase verify voltage V_{VEYEr}. For example, the threshold voltage of the memory cell MC controlled in a state A is larger than a verify voltage V_{VFYA} and smaller than a verify voltage V_{VFYB}. Additionally, for example, the threshold voltage of the memory cell MC controlled in a state B is larger than the verify voltage V_{VFYB} and smaller than a verify voltage V_{VEYC}. Hereinafter, similarly, the threshold voltages of the memory cells MC controlled in a state C to a state F are larger than the verify voltage V_{VFYC} to a verify voltage V_{VFYF} and smaller than a verify voltage V_{VFYD} to a verify voltage V_{VFYG}, respectively. For example, the threshold voltage of the memory cell MC controlled in a state G is larger than the verify voltage V_{VFYG} and smaller than a read pass voltage V_{READ}. The read pass voltage V_{READ} is a voltage, for example, approximately 9 V.

In the example in FIG. 10A, a read voltage V_{CGAR} is set between a threshold distribution corresponding to the state Er and a threshold distribution corresponding to the state A. A read voltage V_{CGBR} is set between the threshold distribution corresponding to the state A and a threshold distribution corresponding to the state B. Hereinafter, similarly, a read voltage V_{CGCR} to a read voltage V_{CGGR} are set between the threshold distribution corresponding to the state B and a threshold distribution corresponding to the state C to between a threshold distribution corresponding to the state F and a threshold distribution corresponding to the state G, respectively.

For example, the state Er corresponds to the lowest threshold voltage. The memory cell MC in the state Er is, for example, the memory cell MC in an erase state. For example, data “111” is assigned to the memory cell MC in the state Er.

The state A corresponds to the threshold voltage higher than the threshold voltage corresponding to the state Er. For example, data “101” is assigned to the memory cell MC in the state A.

The state B corresponds to the threshold voltage higher than the threshold voltage corresponding to the state A. For example, data “001” is assigned to the memory cell MC in the state B.

Hereinafter, similarly, the state C to the state G in the drawing correspond to threshold voltages higher than the threshold voltages corresponding to the state B to the state F. For example, data “011”, “010”, “110”, “100”, and “000” are assigned to the memory cells MC in these states.

In the case of the assignment as exemplified in FIG. 10B, the data of a low-order bit is distinguishable with one read voltage V_{CGDR}. The data of a middle-order bit is distinguishable with three read voltages V_{CGAR}, V_{CGCR}, V_{CGFR}. The data of an high-order bit is distinguishable with three read voltages V_{CGBR}, V_{CGER}, V_{CGGR}. This assignment of data may be referred to as a 1-3-3 code.

The number of bits of the data stored in the memory cell MC, the number of states, the assignment of the data to each state, and the like are changeable as appropriate. For example, in the case of the assignment as exemplified in FIG. 10C, the data of the low-order bit is distinguishable with one read voltage V_{CGDR}. The data of the middle-order bit is distinguishable with the two read voltages V_{CGBR}, V_{CGFR}. The data of the high-order bit is distinguishable with the four read voltages V_{CGAR}, V_{CGCR}, V_{CGER}, V_{CGGR}. This assignment of data may be referred to as a 1-2-4 code.

### Operation

Next, the operation of the semiconductor memory device according to the embodiment is described.

### [Read Operation]

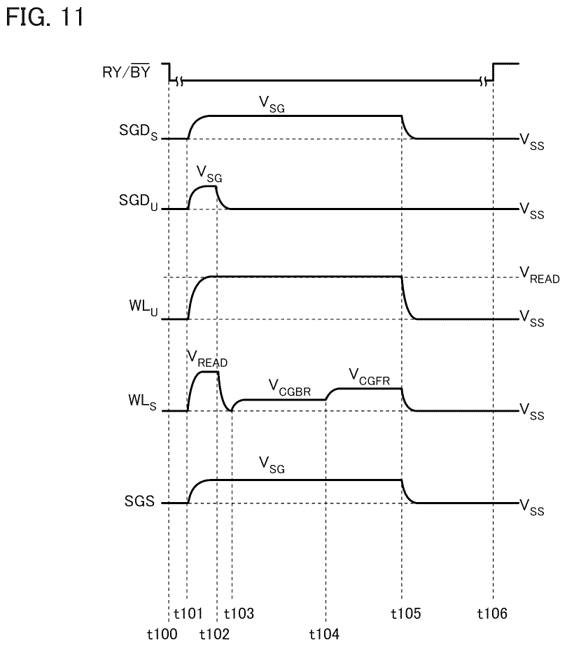

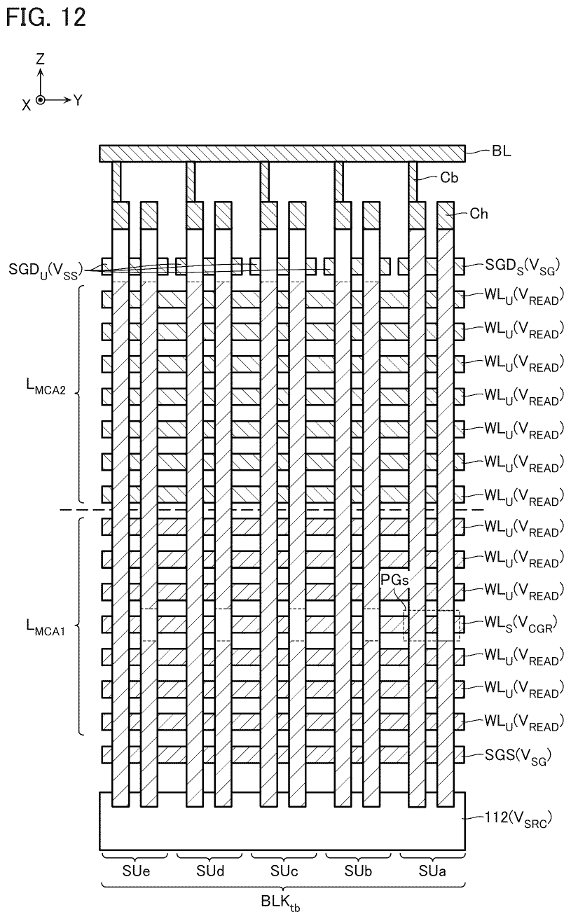

The read operation of the memory die MD according to the embodiment is described. FIG. 11 is a timing chart for describing the read operation. FIG. 12 is a schematic cross-sectional view for describing the read operation. FIG. 12 illustrates respective voltages applied at timing t103 to timing t105 in FIG. 11.

In the following description, the drain-side select gate line SGD corresponding to the string unit SU as an operation target is referred to as a drain-side select gate line SGDs, and the drain-side select gate lines SGD corresponding to the other string units SU are referred to as drain-side select gate lines SGD_{U} in some cases.

The word line WL as an operation target is referred to as a selected word line WL_{S}, and the other word lines WL are referred to as unselected word lines WL_{U} in some cases.

In the following description, an example of performing the read operation on one connected to the selected word line WL_{S} (hereinafter referred to as a “selected memory cell MC” in some cases) among the plurality of memory cells MC included in the string unit SU (FIG. 12) as an operation target is described. In the following description, a configuration including such a plurality of the selected memory cells MC is referred to as a selected page PGs in some cases. Additionally, the memory block BLK including the selected page PGs is referred to as a selected memory block BLK_{tb} in some cases.

An example in which each of the memory cells MC stores data of a plurality of bits and a plurality of read voltages are used in the read operation is described below.

At timing t100 of the read operation, the controller die CD sequentially inputs the command data Cmd (FIG. 4) instructing the read operation and the address data Add (FIG. 4) to the memory die MD. Thus, the terminal RY/(/BY) enters a period in an “L” state (busy period).

At timing t101, for example, as illustrated in FIG. 11, a voltage V_{SG} is applied to the drain-side select gate line SGDs, the drain-side select gate line SGD_{U}, and the source-side select gate line SGS to turn all the select transistors (STD, STS) in an ON state. The read pass voltage V_{READ} is applied to the selected word line WL_{S} and the read pass voltage V_{READ} is applied to the unselected word lines WL_{U} to turn all the memory cells MC in an ON state.

At timing t102, for example, as illustrated in FIG. 11, the read pass voltage V_{READ} is applied to the unselected word line WL_{U} to turn all the memory cells MC connected to the unselected word line WL_{U} in an ON state. Meanwhile, the ground voltage V_{SS} is applied to the selected word line WL_{S} to turn the memory cell MC connected to the selected word line WL_{S} in an OFF state. The voltage V_{SG} is applied to the drain-side select gate line SGDs and the source-side select gate line SGS of the string unit SUa including the selected page PGs to turn the select transistors STD, STS connected to them in an ON state. The ground voltage V_{SS} is applied to the drain-side select gate lines SGD_{U} of the string units SUb to SUe not including the selected page PGs to turn the select transistors STD connected to them in an OFF state.

At timing t103, a predetermined read voltage V_{CGR} is applied to the selected word line WL_{S}. The read voltage V_{CGR} may be, for example, any of the seven read voltages V_{CGAR} to V_{CGGR} described with reference to FIG. 10A. Thus, the selected memory cell MC included in the selected page PGs turns to an ON state or an OFF state according to each threshold voltage. That is, a part of the selected memory cells MC of the selected page PGs turns to an ON state, and the remaining selected memory cells MC turn to an OFF state.

At timing t103 to timing t104 of the read operation, for example, the bit lines BL are charged. Additionally, for example, the voltage V_{SRC} is applied to the source line SL (semiconductor layer 112) to start charging them. The voltage V_{SRC}, for example, has about the same magnitude as a magnitude of the ground voltage V_{SS}. Subsequently, the sense amplifier module SAM (FIG. 4) performs a sense operation that detects the ON state/OFF state of the memory cell MC to acquire data indicative of the state of this memory cell MC.

At timing t104 of the read operation, another read voltage V_{CGR} is applied to the selected word line WL_{S}. Thus, a part of the selected memory cells MC of the selected pages PGs turns to an ON state, and the remaining selected memory cells MC turn to an OFF state.

At timing t104 to timing t105 of the read operation, similarly to timing t103 to timing t104, the sense operation is performed by the sense amplifier module SAM and data indicative of the state of this memory cell MC is acquired.

At timing t105 of the read operation, the ground voltage V_{SS} is applied to the selected word line WL_{S}, all the unselected word lines WL_{U}, and the select gate lines (SGD, SGS).

At timing t106, the read operation in the memory die MD ends. The terminal RY/(/BY) turns from the “L” state to the “H” state, and the access to the memory die MD is permitted.

Note that in the read operation, arithmetic processing, such as AND and OR, is performed on the data indicative of the state of the above-described memory cell MC, and thus, the data stored in the memory cell MC is calculated. This data is transferred to the cache memory CM (FIG. 4).

### [Write Operation]

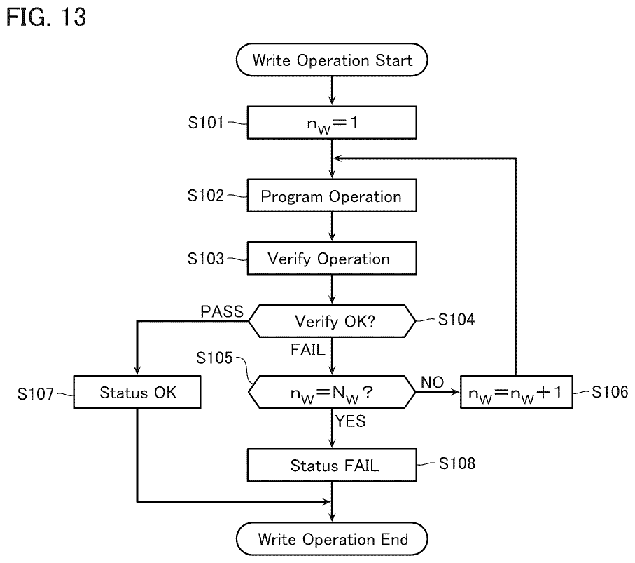

Next, the write operation of the memory die MD according to the embodiment is described. FIG. 13 is a flowchart for describing the write operation.

In the following description, an example of performing the write operation on a plurality of selected memory cells MC corresponding to the selected page PGs is described.

At Step S101, a loop count n_{W} is set to 1. The loop count n_{W} is a variable indicative of the count of write loop.

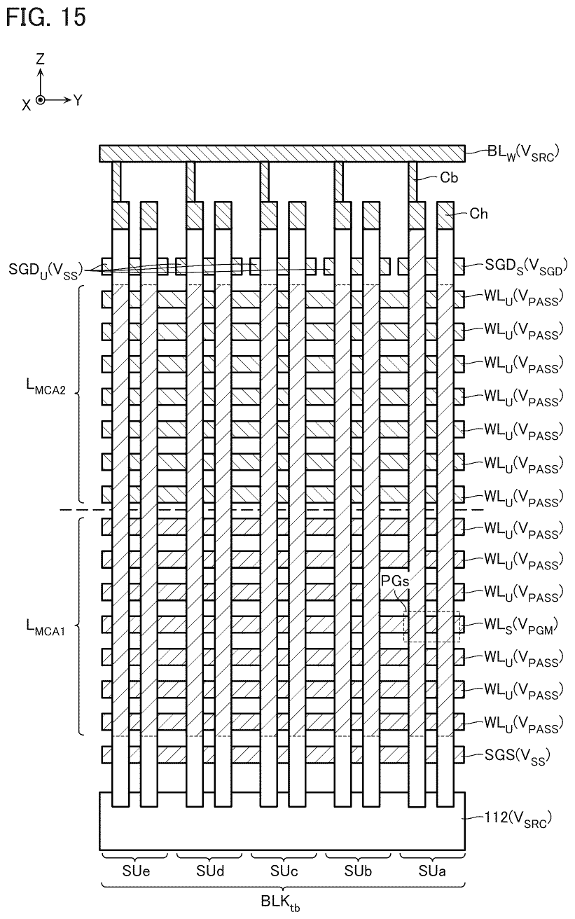

At Step S102, a program operation is performed. The program operation is an operation that applies a program voltage V_{PGM} (FIG. 15) to the selected word line WL_{S} to increase the threshold voltage of the memory cell MC.

At Step S103, a verify operation is performed. The verify operation is basically performed similarly to the read operation described with reference to FIG. 11 and FIG. 12. However, in the verify operation, instead of the predetermined read voltage V_{CGR}, for example, the verify voltage V_{VFYA} to the verify voltage V_{VFYG} described with reference to FIG. 10A to FIG. 10C are applied to the selected word line WL_{S}, and the ON state/OFF state of the memory cell MC is detected, thereby detecting whether the threshold voltage of the memory cell MC reaches the target value or not.

At Step S104, the result of the verify operation is determined. For example, by referring to a counter circuit (not illustrated), the number of the memory cells MC whose threshold voltages have not reached the target value is counted. For example, when the number of the memory cells MC whose threshold voltages have not reached the target value is a certain number or more, it is determined to be verify FAIL and the procedure proceeds to Step S105. On the other hand, for example, when the number of the memory cells MC whose threshold voltages have not reached the target value is less than the certain number, it is determined to be verify PASS and the procedure proceeds to Step S107.

At Step S105, whether the loop count n_{W} has reached a predetermined count N_{W} or not is determined. When it has not reached the predetermined count N_{W}, the procedure proceeds to Step S106. When it has reached the predetermined count N_{W}, the procedure proceeds to Step S108.

At Step S106, 1 is added to the loop count n_{W}, and the procedure proceeds to Step S102. At Step S106, for example, the program voltage V_{PGM} (FIG. 15) applied to the selected word line WL_{S} in the program operation is increased by a predetermined voltage ΔV. Therefore, the program voltage V_{PGM} increases together with the increase in the loop count n_{W}.

At Step S107, status data Stt indicative of normal termination of the write operation is stored in a status register STR (FIG. 4) to terminate the write operation. The status data Stt is output to the controller die CD (FIG. 1) by a status read operation.

At Step S108, status data Stt indicative of failing to normally terminate the write operation is stored in the status register STR (FIG. 4) to terminate the write operation.

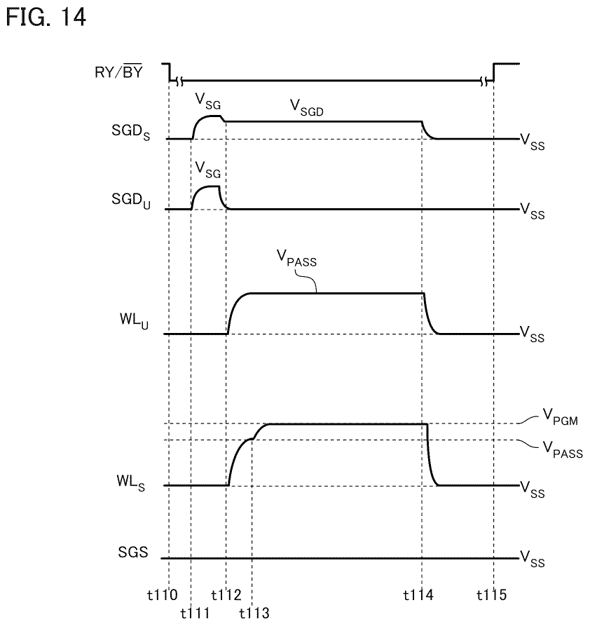

FIG. 14 is a timing chart for describing the write operation. FIG. 15 is a schematic cross-sectional view for describing the write operation. FIG. 15 illustrates the respective voltages applied at timing t113 to timing t114 in FIG. 14.

Hereinafter, the selected memory cell MC on which the adjustment of the threshold voltage is performed among the plurality of selected memory cells MC is referred to as a “write memory cell MC” and the selected memory cell MC on which the adjustment of the threshold voltage is not performed is referred to as an “inhibited memory cell MC” in some cases.

At timing t110 of the write operation, for example, as illustrated in FIG. 14, the controller die CD sequentially inputs the command data Cmd (FIG. 4) instructing the write operation and the address data Add (FIG. 4) to the memory die MD. Thus, the terminal RY/(/BY) enters a period in an “L” state (busy period).

At the timings t110 to t111, for example, the voltage V_{SRC} is applied to the bit line BL_{W} (FIG. 15) connected to the write memory cell MC, and the voltage V_{DD} is applied to the bit line BL connected to the inhibited memory cell MC. The voltage V_{SRC} is applied to the source line SL (semiconductor layer 112).

At timing t111, the voltage V_{SG} is applied to the drain-side select gate line SGDs and the drain-side select gate line SGD_{U} to turn all the drain-side select transistors STD in an ON state.

At timing t112, the voltage V_{SGD} is applied to the drain-side select gate line SGDs. The voltage V_{SGD} is smaller than the voltage V_{SG}, and has a magnitude approximately turning the drain-side select transistor STD to the ON state or the OFF state corresponding to the voltage of the bit line BL. The ground voltage V_{SS} is applied to the drain-side select gate line SGD_{U} and the source-side select gate line SGS to turn the select transistors (STD, STS) connected to the drain-side select gate line SGD_{U} and the source-side select gate line SGS to the OFF state. The write pass voltage V_{PASS} is applied to the selected word line WL_{S} and the unselected word line WL_{U}. The write pass voltage V_{PASS} may have a magnitude approximately the same as the read pass voltage V_{READ} described with reference to FIG. 12, or may be larger than the read pass voltage V_{READ}.

At timing t113, the program voltage V_{PGM} is applied to the selected word line WL_{S}. The program voltage V_{PGM} is larger than the write pass voltage V_{PASS}.

Here, for example, as illustrated in FIG. 15, the voltage V_{SRC} is applied from the bit line BL to the channel of the semiconductor layer 120 connected to the bit line BL_{W}. A comparatively large electric field is generated between the semiconductor layer 120 and the selected word line WL_{S}. This causes the electrons in the channel of the semiconductor layer 120 to tunnel into the electric charge accumulating film 132 (FIG. 9) via the tunnel insulating film 131 (FIG. 9). This increases a threshold voltage of the write memory cell MC.

Additionally, the channel of the semiconductor layer 120 connected to the bit line BL other than the bit line BL_{W} is in an electrically floating state, and this channel voltage is increased up to approximately the write pass voltage V_{PASS} by capacitive coupling with the unselected word line WL_{U}. Between such a semiconductor layer 120 and the selected word line WL_{S}, only an electric field smaller than the above-described electric field is generated. Accordingly, the electrons in the channel of the semiconductor layer 120 do not tunnel into the electric charge accumulating film 132 (FIG. 9). Accordingly, the threshold voltage of the inhibited memory cell MC does not increase.

At timing t114, the ground voltage V_{SS} is applied to the selected word line WL_{S}, the unselected word line WL_{U}, the drain-side select gate line SGDs, the drain-side select gate line SGD_{U}, and the source-side select gate line SGS.

At timing t115, the write operation in the memory die MD ends. The terminal RY/(/BY) turns from the “L” state to the “H” state, and the access to the memory die MD is permitted.

### [Memory Block Erase Operation]

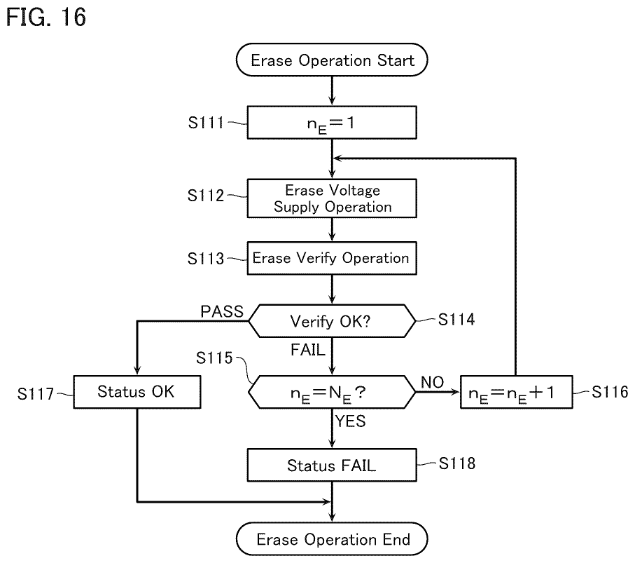

Next, a memory block erase operation of the memory die MD according to the embodiment is described. FIG. 16 is a flowchart for describing the erase operation.

In the following description, an example in which the erase operation is performed on a selected memory block BLK_{tb} as an operation target is described.

At Step S111, for example, as illustrated in FIG. 16, a loop count n_{E} is set to 1. The loop count n_{E} is a variable indicative of the count of erase loop.

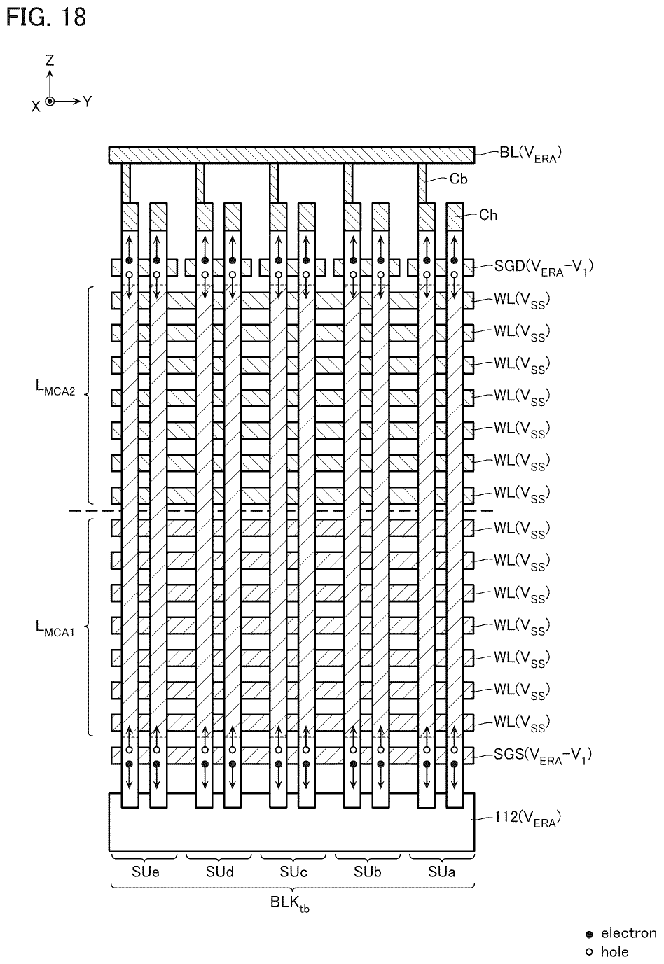

At Step S112, an erase voltage supply operation is performed. The erase voltage supply operation is an operation that applies the ground voltage V_{SS} to the word line WL and applies a voltage V_{ERA} (FIG. 18, referred to as an erase voltage in some cases) to at least one of the source line SL and the bit line BL to reduce the threshold voltage of the memory cell MC.

At Step S113, an erase verify operation is performed. The erase verify operation is an operation for applying an erase verify voltage V_{VFYEr} to the word line WL, detecting the ON state/OFF state of the memory cell MC, and detecting whether the threshold voltage of the memory cell MC reaches the target value or not.

At Step S114, the result of the erase verify operation is determined. For example, with reference to the above-described counter circuit, the number of the memory cells MC whose threshold voltages have not reached the target value. For example, when the number of the memory cells MC whose threshold voltages have not reached the target value is a certain number or more, it is determined to be verify FAIL and the procedure proceeds to Step S115. On the other hand, for example, when the number of the memory cells MC whose threshold voltages have not reached the target value is less than the certain number, it is determined to be verify PASS and the procedure proceeds to Step S117.

At Step S115, whether the loop count n_{E} has reached a predetermined count N_{E} or not is determined. When it has not reached the predetermined count N_{E}, the procedure proceeds to Step S116. When it has reached the predetermined count N_{E}, the procedure proceeds to Step S118.

At Step S116, 1 is added to the loop count n_{E}, and the procedure proceeds to Step S112. At Step S116, for example, a predetermined voltage ΔV is added to the voltage V_{ERA} (FIG. 18) applied to at least one of the source line SL and the bit line BL in the erase voltage supply operation. Therefore, the voltage V_{ERA} (FIG. 18) increases together with the increase in the loop count n_{E}.

At Step S117, status data Stt indicative of normal termination of the erase operation is stored in the status register STR (FIG. 4) to terminate the erase operation. The status data Stt is output to the controller die CD (FIG. 1) by a status read operation.

At Step S118, status data Stt indicative of failing to normally terminate the erase operation is stored in the status register STR (FIG. 4) to terminate the erase operation.

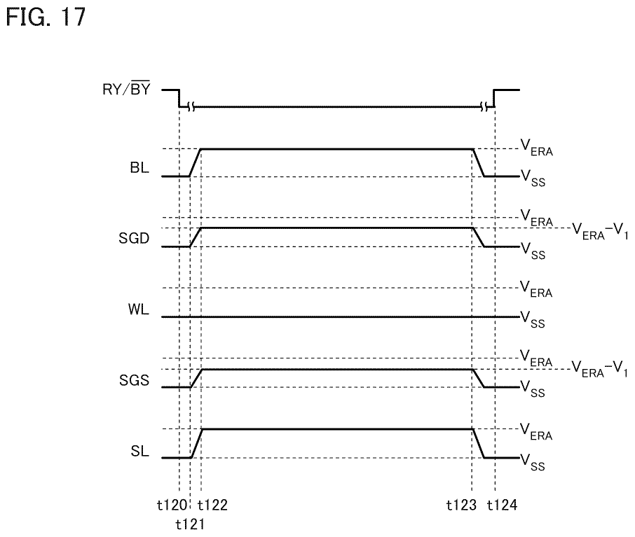

FIG. 17 is a timing chart for describing the erase operation. FIG. 18 is a schematic cross-sectional view for describing the erase operation. FIG. 18 illustrates the respective voltages applied at timing t122 to timing t123 in FIG. 17.

At timing t120 of the erase operation, the controller die CD sequentially inputs the command data Cmd instructing the erase operation and the address data Add to the memory die MD. Thus, the terminal RY/(/BY) enters a period in an “L” state (busy period).

At timing t121 of the erase operation, a voltage V_{ERA}-V₁ is applied to each of the select gate lines (SGD, SGS), and the ground voltage V_{SS} is applied to the word line WL. The voltage V_{ERA}-V₁ applied to the select gate lines (SGD, SGS) is larger than the ground voltage V_{SS} applied to the word line WL. The voltage V_{ERA} is applied to the bit line BL and the source line SL (semiconductor layer 112). At timing t121 of the erase operation, the voltage V_{ERA}-V₁ may be applied to only any one of the drain-side select gate line SGD and the source-side select gate line SGS. When the voltage V_{ERA}-V₁ is applied to the drain-side select gate line SGD, the voltage V_{ERA} may be applied to the bit line BL. When the voltage V_{ERA}-V₁ is applied to the source-side select gate line SGS, the voltage V_{ERA} may be applied to the source line SL.

At timing t122 to timing t123, data written in the memory cell MC is erased by Gate Induced Drain Leakage (GIDL) described later.

At timing t123, the ground voltage V_{SS} is applied to the bit line BL, the select gate lines (SGD, SGS), and the word line WL.

At timing t124, the erase operation in the memory die MD ends. The terminal RY/(/BY) turns from the “L” state to the “H” state, and the access to the memory die MD is permitted.

### [Erase Operation by GIDL]

At timing t122 to timing t123 of FIG. 17, as illustrated in FIG. 18, via the select gate lines (SGD, SGS), the voltage V_{ERA}-V₁ is applied to the gate electrodes of the select transistors (STD, STS). Via the bit line BL and the source line SL, the voltage V_{ERA} is applied to the channel regions of the select transistors (STD, STS). Accordingly, a voltage V₁ is applied between the gate electrodes and the channel regions of the select transistors (STD, STS).

The voltage V₁ is, for example, a voltage having a magnitude to the extent that GIDL occurs at or near the channels (a surface of the semiconductor layer 120) of the select transistors (STD, STS). By GIDL, for example, as illustrated in FIG. 18, the electron-hole pairs occur at or near the channel of each of the select transistors (STD, STS).

The electrons generated in the drain-side select transistor STD are supplied to the bit line BL side, and the holes are supplied to the memory cell MC side. The electrons generated in the source-side select transistor STS are supplied to the source line SL side, and the holes are supplied to the memory cell MC side. In association with this, the holes are accumulated on the channel region of the memory cell MC, and the voltage of the channel region of the memory cell MC increases.

At timing t122 to timing t123 of FIG. 17, the ground voltage V_{SS} is applied to the word line WL. Therefore, between the gate electrode and the channel region of the memory cell MC, a voltage around the voltage V_{ERA} is applied. This voltage has a magnitude to the extent that the holes supplied by GIDL can tunnel the tunnel insulating film 131 and reach the electric charge accumulating film 132.

Thus, by accumulating the holes generated by the GIDL on the electric charge accumulating films 132 (FIG. 9) of all the memory cells MC included in the selected memory block BLK_{tb}, threshold voltage of the memory cell MC is reduced to erase data in the memory cell MC.

### [Erase Verify Operation]

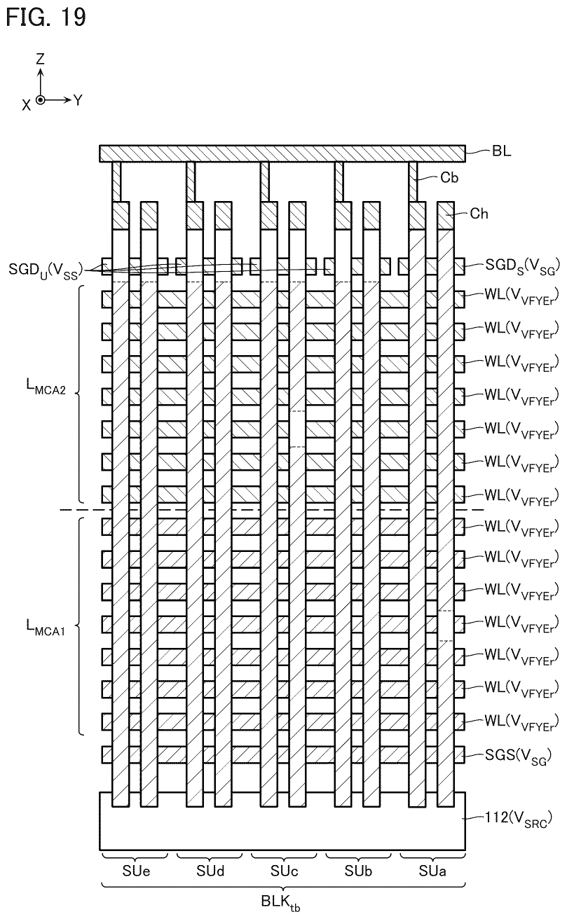

FIG. 19 is a schematic cross-sectional view for describing the erase verify operation. For example, as illustrated in FIG. 19, in the erase verify operation, the voltage V_{SG} is applied to the drain-side select gate line SGDs and the source-side select gate line SGS of the string unit SUa to turn ON the select transistors STD, STS connected to the drain-side select gate line SGDs and the source-side select gate line SGS. The ground voltage V_{SS} is applied to the drain-side select gate lines SGD_{U} of the other string units SUb to SUe to turn OFF the select transistors STD connected to the drain-side select gate lines SGD_{U}. The erase verify voltage V_{VFYEr} is applied to the word line WL to detect whether or not the threshold voltages of the memory cells MC included in the string unit SUa have reached the target value.

### [Sub-Block Erase Mode]

In association with the high integration of the semiconductor memory device, the number of bits for each memory block BLK is increasing. Accordingly, the erase unit increases, thus increasing the number of the write operations at garbage collection. Therefore, the semiconductor memory device according to the first embodiment is configured to be operable in a sub-block erase mode. In the sub-block erase mode, one memory block BLK is divided into two sub-blocks, and the sub-block can be used as an erase unit. In the sub-block erase mode, for example, among the configurations in the memory block BLK, a configuration included in the memory cell array layer L_{MCA1} described with reference to FIG. 8 is used as one sub-block SB1, and a configuration included in the memory cell array layer L_{MCA2} is used as another sub-block SB0.

### [Select Erase Operation (1)]

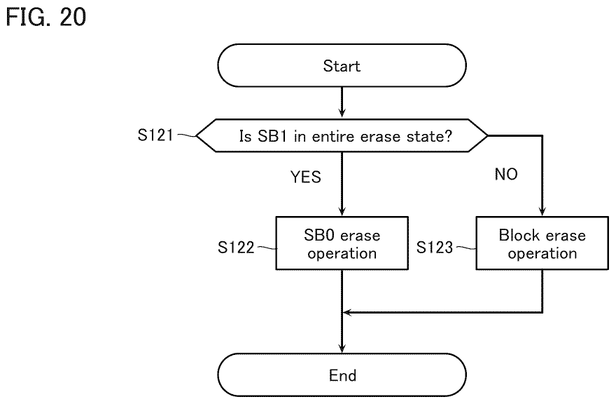

The semiconductor memory device according to the embodiment is configured to be able to perform a select erase operation (1). FIG. 20 is a flowchart for describing the select erase operation (1).

In an example described below, in the memory block BLK, the write operation is performed on the sub-block SB0 first, and subsequently, the write operation is performed on the sub-block SB1.

In the following description, when it is referred that the sub-block SB is in an entire erase state, it means that all the pages PG included in the sub-block SB and all the memory cells MC included in the pages PG are in an erase state.

At Step S121, whether or not the sub-block SB1 is in the entire erase state is determined. When the sub-block SB1 is in the entire erase state, the procedure proceeds to Step S122, and when the sub-block SB1 is not in the entire erase state, the procedure proceeds to Step S123. The operation to determine whether or not the sub-block SB1 is in the entire erase state is described later.

At Step S122, a sub-block SB0 erase operation described later is performed.

At Step S123, the above-described memory block erase operation (FIG. 16) is performed.

[Operation to Determine Whether or Not Sub-Block SB1 is in Entire erase state]

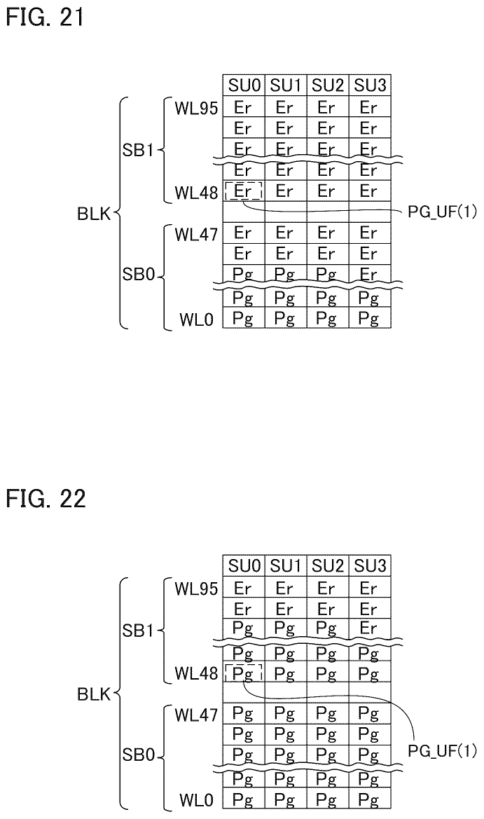

FIG. 21 to FIG. 23 are schematic diagrams illustrating examples of a write status of the sub-block.

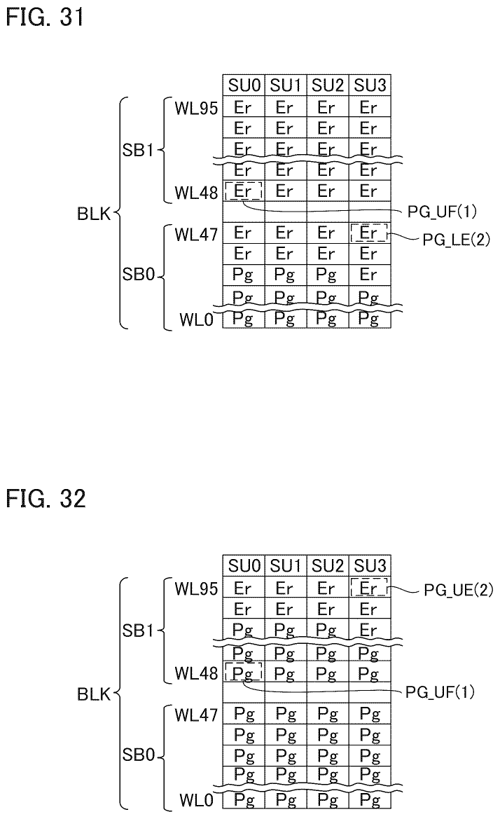

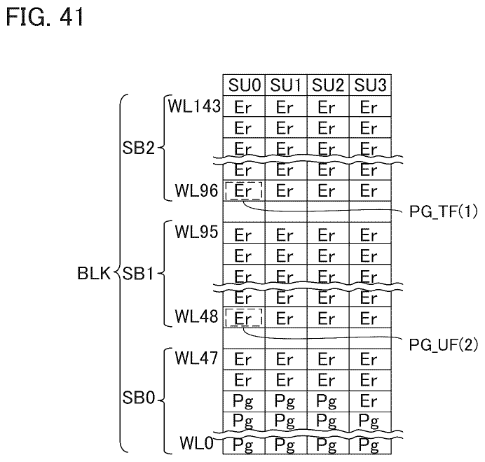

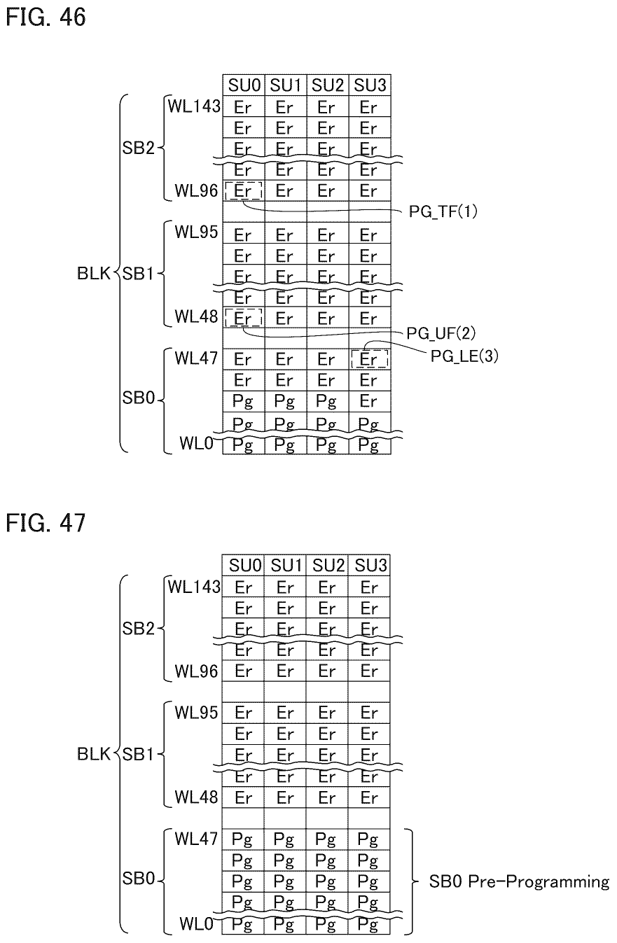

Hereinafter, FIG. 21 to FIG. 23, FIG. 31 to FIG. 34, FIG. 41 to FIG. 44, and FIG. 46 to FIG. 51 illustrate the write statuses of the pages PG corresponding to a plurality of word lines WL and four string units SU0, SU1, SU2, SU3 disposed in the memory block BLK. The write status of the page PG is indicated as any of a write state Pg or an erase state Er.

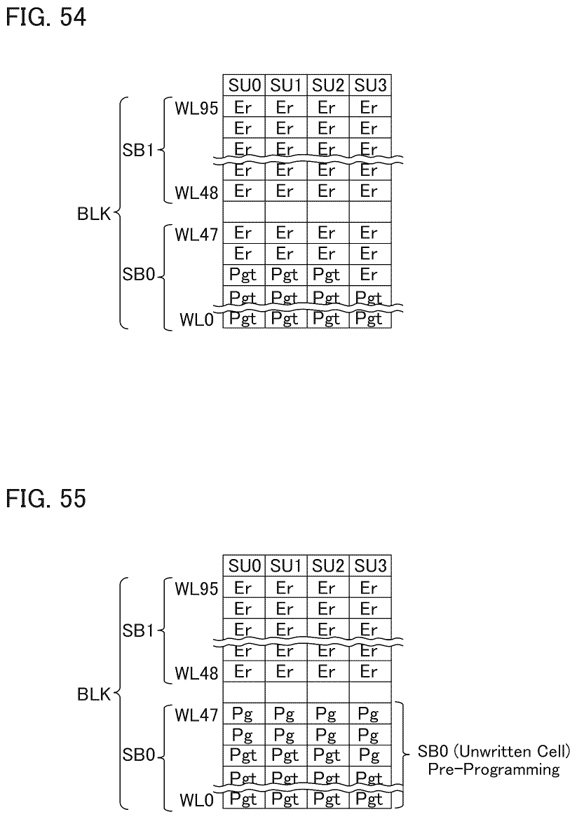

In the examples below illustrated in FIG. 21 to FIG. 23, FIG. 31 to FIG. 34, and FIG. 54 to FIG. 57, the 96 layers of the word lines WL are disposed in total, and the n-th (n is an integer of 1 to 96) word line WL counted from one side is indicated as a word line WL (n−1). In the examples of FIG. 21 and FIG. 22, the sub-block SB0 includes the word lines WL0 to WL47, and the sub-block SB1 includes the word lines WL48 to WL95.

In the examples illustrated in FIG. 21 to FIG. 23, FIG. 31 to FIG. 34, and FIG. 54 to FIG. 57, the write operation is performed on from the word line WL0 to the word line WL95 in ascending order of n of the word line WL (n−1), and in each of the word lines WL, the write operation is performed in the order of the string units SU0, SU1, SU2, and SU3.

This determination operation is, for example, one of operations performed inside the memory die MD when a command instructing the erase operation on the selected memory block BLK is transmitted to the memory die MD.

In this operation, for example, as illustrated in FIG. 21 and FIG. 22, the read operation is performed on a page PG_UF (1) on which the write operation is performed first among the pages PG in the sub-block SB1. In the examples illustrated in FIG. 21 and FIG. 22, the page PG_UF (1) is a page PG corresponding to the word line WL48 and the string unit SU0 in the sub-block SB1.

FIG. 21 illustrates a case where the sub-block SB1 is in the entire erase state and the sub-block SB0 is not in the entire erase state. In this case, when a result that the page PG_UF (1) is in the erase state Er is obtained by the read operation, the sub-block SB1 can be determined to be in the entire erase state.

FIG. 22 illustrates a case where the sub-block SB1 is not in the entire erase state. When a result that the page PG_UF (1) is in the write state Pg is obtained by the read operation, the sub-block SB1 can be determined to be not in the entire erase state.

### [Sub-Block SB0 Erase Operation]

The sub-block SB0 erase operation is an operation to erase data of all the memory cells MC in the sub-block SB0. The erase operation of the sub-block SB0 is basically performed similarly to the memory block erase operation (FIG. 16). However, an erase voltage supply operation performed in the sub-block SB0 erase operation is different from the erase voltage supply operation performed in the memory block erase operation (FIG. 16).

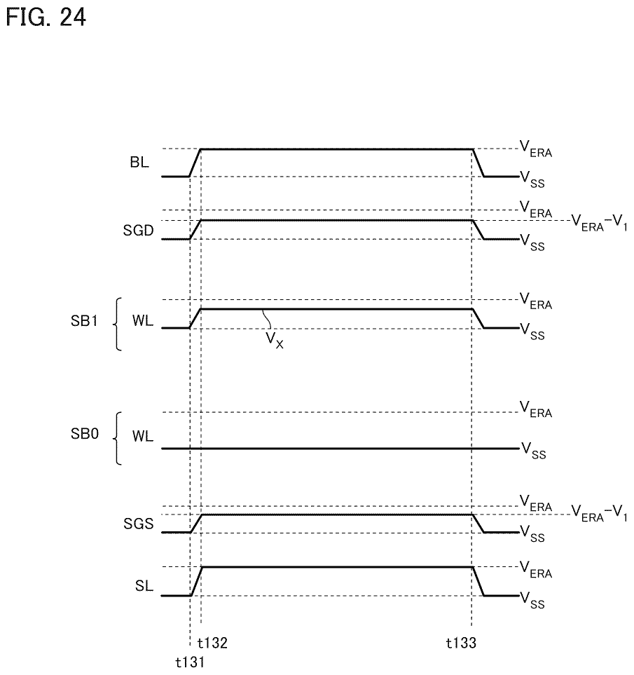

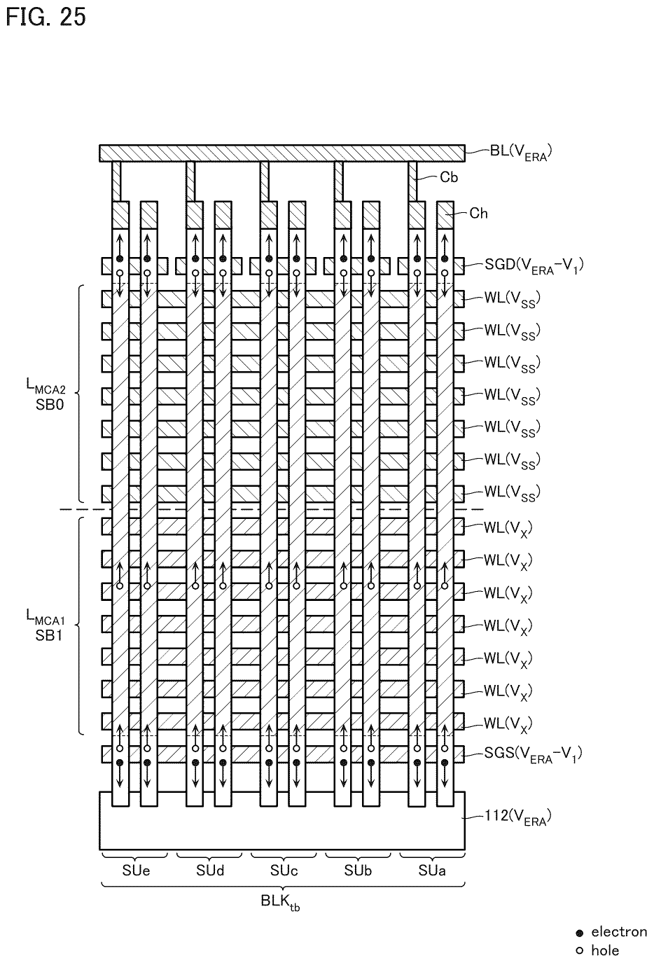

FIG. 24 is a timing chart for describing the sub-block SB0 erase operation. FIG. 25 is a schematic cross-sectional view for describing the sub-block SB0 erase operation.

At timing t131 of the sub-block SB0 erase operation, as illustrated in FIG. 24 and FIG. 25, the voltage V_{ERA}-V₁ is applied to each of the select gate lines (SGD, SGS), and the voltage V_{ERA} is applied to the bit line BL and the source line SL (semiconductor layer 112).

The ground voltage V_{SS} is applied to the word line WL of the sub-block SB0. Accordingly, a voltage about the voltage V_{ERA} is applied between the gate electrode and the channel region of the memory cell MC in the sub-block SB0.

An unselect erase voltage V_{X} larger than the ground voltage V_{SS} is applied to the word line WL of the sub-block SB1. Accordingly, a voltage V_{ERA}-V_{X} smaller than the voltage V_{ERA} is applied between the gate electrode and the channel region of the memory cell MC in the sub-block SB1. The voltage V_{ERA}-V_{X} is a voltage to the extent that the holes do not tunnel the tunnel insulating film 131 even when the memory cell MC in the sub-block SB1 is in the Er state, that is, in a state where the electrons are not accumulated in the electric charge accumulating film 132. The voltage V_{ERA}-V_{X} has a magnitude to the extent that the memory cell MC turns ON when the memory cell MC is operated as a PMOS transistor.

At timing t132 to timing t133, in the memory cell MC of the sub-block SB0, holes that have tunneled the tunnel insulating film 131 are accumulated in the electric charge accumulating film 132 (FIG. 9), thereby erasing the data of the memory cell MC. On the other hand, in the memory cell MC of the sub-block SB1, since holes do not tunnel the tunnel insulating film 131, further drop (over erase) of the threshold of the memory cell MC does not occur.

In the erase voltage supply operation performed in the sub-block SB0 erase operation, as illustrated in FIG. 25, the holes occurred at or near the channel of the select transistor STS may be used for the erase of the memory cell MC. The holes occurred at or near the channel of the select transistor STD may be transmitted to the sub-block SB0 via the channel region corresponding to the sub-block SB1 and used for the erase of the memory cell MC.

At timing t133, the ground voltage V_{SS} is applied to the bit line BL, the select gate lines (SGD, SGS), the word lines WL of the sub-block SB0 and the sub-block SB1, and the source line SL.

### [Exemplary Operation of Select Erase Operation (1)]

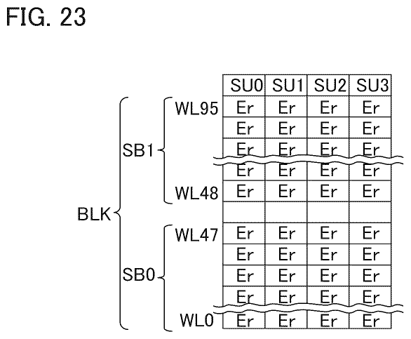

An operation when the sub-block SB1 is in the entire erase state (FIG. 21) is referred to as an operation example EX10. In the operation example EX10, at Step S121, the read operation on the page PG_UF (1) is performed. Further, the sub-block SB0 erase operation at Step S122 is performed, and thus all the pages PG included in the memory block BLK become in the erase state Er (FIG. 23).

An operation when the sub-block SB1 is not in the entire erase state (FIG. 22) is referred to as an operation example EX11. In the operation example EX11, at Step S121, the read operation is performed on the page PG_UF (1). Further, in the operation example EX11, the memory block erase operation at Step S123 is performed, and thus all the pages PG included in the memory block BLK become in the erase state Er (FIG. 23).

### [Threshold Voltage Distribution of Memory Cell MC by Erase Operation]

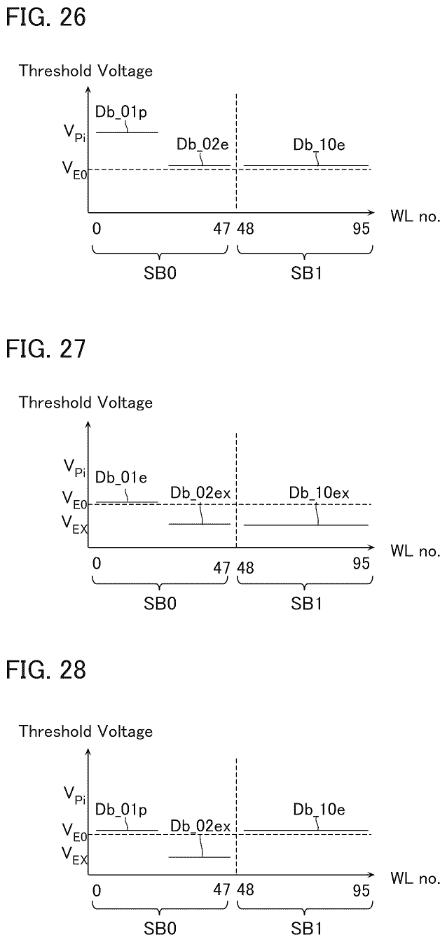

FIG. 26 and FIG. 28 are graphs for describing the semiconductor memory device according to the embodiment. Hereinafter, FIG. 26 to FIG. 28 indicate medians of the threshold voltages of a plurality of memory cells MC in the pages PG corresponding to the respective word lines WL having the word lines WL0 to WL95 as the horizontal axis.

FIG. 26 is a diagram corresponding to the case where the sub-block SB0 is in a partial write state and the sub-block SB1 is in the entire erase state (FIG. 21). Since the pages PG corresponding to a plurality of word lines WL positioned on one side of the sub-block SB0 are in the write state Pg, the median of the threshold voltage is, for example, approximately a voltage V_{Pi} (group Db_01p in FIG. 26). Since the pages PG corresponding to a plurality of word lines WL positioned on the other side of the sub-block SB0 are in the erase state Er, the median of the threshold voltage is, for example, approximately a voltage V_{E0} (group Db_02e in FIG. 26). Since the pages PG corresponding to all the word lines WL of the sub-block SB1 are in the erase state Er, the median of the threshold voltage is, for example, approximately the voltage V_{E0} (group Db_10e in FIG. 26).

### COMPARATIVE EXAMPLE

Next, a semiconductor memory device according to a comparative example is described. FIG. 27 is a graph for describing the semiconductor memory device according to the comparative example. In the semiconductor memory device according to the comparative example, the memory block erase operation is performed regardless of the write status of the sub-block.

FIG. 27 is a diagram when the memory block erase operation (FIG. 16) is performed on the memory block BLK in the state corresponding to FIG. 21 and FIG. 26. By the memory block erase operation, the pages PG corresponding to a plurality of word lines WL positioned on one side of the sub-block SB0 turn from the write state Pg to the erase state Er, and the median of the threshold voltage becomes, for example, approximately the voltage V_{E0} (group Db_01e in FIG. 27). On the other hand, the pages PG corresponding to a plurality of word lines WL positioned on the other side of the sub-block SB0 are in the erase state Er, and further, application of the voltage of about the voltage V_{ERA} between the gate electrode and the channel region of the memory cell MC causes the holes to be excessively injected into the electric charge accumulating film 132 (FIG. 9). Therefore, the median of the threshold voltage becomes, for example, a voltage V_{EX} lower than the voltage V_{E0} (group Db_02ex in FIG. 27). For the pages PG included in all the word lines WL of the sub-block SB1, similarly, the median of the threshold voltage becomes, for example, the voltage V_{EX} (group Db_10ex in FIG. 27).

As in the groups Db_02ex, Db_10ex, the drop of the threshold voltage after the erase operation to the voltage V_{EX} lower than the ordinary voltage V_{E0} is hereinafter referred to as an over erase state. When a high voltage is applied to the gate electrode of the memory cell MC until the over erase state occurs, an excessive stress is applied on the gate insulating film of the memory cell MC. In such a case, the data retention characteristic of the memory cell MC is reduced in some cases.

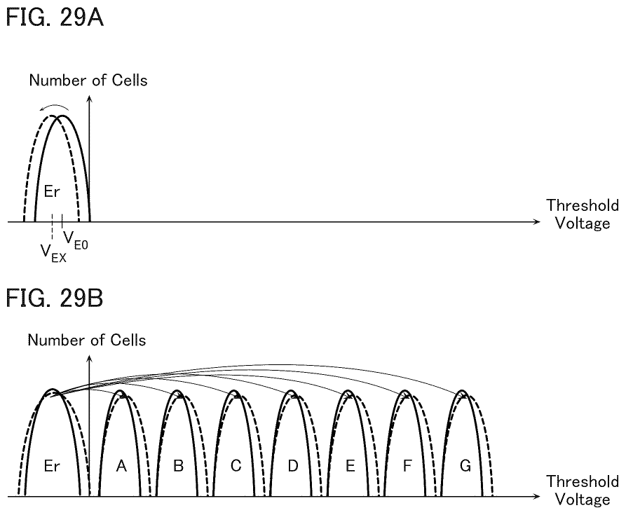

FIG. 29A and FIG. 29B are histograms for describing the semiconductor memory device according to the comparative example. In FIG. 29A and FIG. 29B, the horizontal axis indicates the threshold voltage of the word line WL, and the vertical axis indicates the number of the memory cells MC.

FIG. 29A illustrates a threshold voltage distribution (solid line, the median is the voltage V_{E0}) of a plurality of memory cells MC in an original state Er, and a threshold voltage distribution (dashed line, the median is the voltage V_{EX}) of a plurality of memory cells MC in a state Er in the over erase state.

FIG. 29B illustrates threshold voltage distributions (solid lines) when the write operation is performed from the original state Er to the respective state A to state G, and threshold voltage distributions (dashed lines) when the write operation is performed from the state Er in the over erase state to the respective state A to state G. Thus, when the state A to the state G written from the different Er states are mixed, the threshold voltage distributions of the respective states expand, resulting in the reduced reliability, for example, occurrence of failure in the read operation and the like, in some cases.

### Effects

In the semiconductor memory device according to the embodiment, the select erase operation (1) avoids application of the erase voltage to the memory cell MC included in the sub-block SB1 in the entire erase state.

FIG. 28 is a diagram when the select erase operation (1) is performed on the memory block BLK in the state corresponding to FIG. 21 and FIG. 26. By not applying the erase voltage to the sub-block SB1 in the entire erase state, the median of the threshold voltage is kept at, for example, the voltage V_{E0} (group Db_10e in FIG. 28). Accordingly, the excessive stress on the memory cell MC included in the sub-block SB1 and the over erase state of the memory cell MC can be avoided, thereby allowing providing the semiconductor memory device having the satisfactory data retention characteristic and reliability.

### Modification of First Embodiment

In a semiconductor memory device according to the modification, a controller die CD includes a register RG or the like possible to store the erase state and the write state for each sub-block.

At Step S121 (FIG. 20) of this modification, the controller determines whether or not the sub-block SB1 is in the entire erase state by referring to the register RG and the like.

At Step S122 (FIG. 20) of this modification, the controller transmits the command instructing the sub-block SB0 erase operation to the memory die MD, and the memory die MD executes the sub-block SB0 erase operation. At Step S123 (FIG. 20) of this modification, the controller transmits the command instructing the memory block erase operation to the memory die MD, and the memory die MD executes the memory block erase operation (FIG. 16).

### Second Embodiment

Next, a semiconductor memory device according to a second embodiment is described. In the following description, for configurations and operations similar to those of the first embodiment, the explanation may be omitted.

The semiconductor memory device according to the embodiment is basically configured similarly to the semiconductor memory device according to the first embodiment. However, the semiconductor memory device according to the embodiment is configured to be able to perform a select erase operation (2).

### [Select Erase Operation (2)]

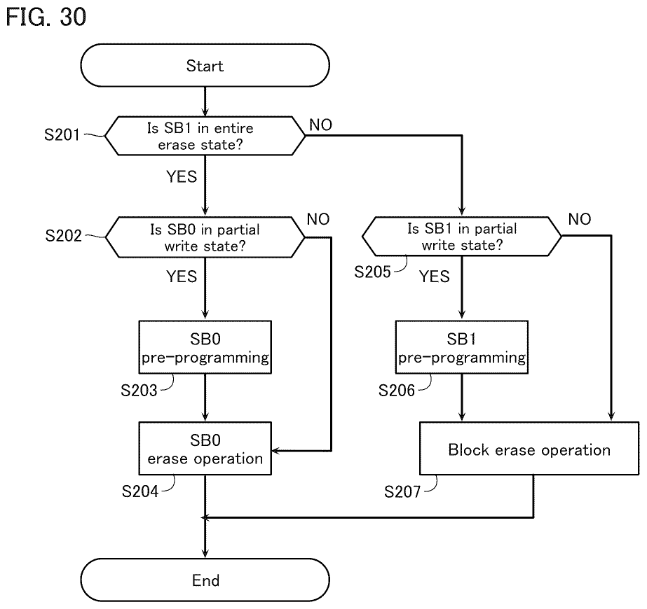

FIG. 30 is a flowchart for describing the select erase operation (2).

In an example below, in the memory block BLK, the write operation is performed on the sub-block SB0 first, and subsequently, the write operation is performed on the sub-block SB1.

In the following description, when it is referred that the sub-block SB is in a partial write state, it means that a part of the pages PG included in the sub-block SB are in the write state Pg and the other pages PG are in the erase state Er. When it is referred that the sub-block SB is not in the partial write state, and when it is referred that the sub-block SB is in the entire erase state, it means that all the pages PG included in the sub-block SB are in the write state Pg.

At Step S201, whether or not the sub-block SB1 is in the entire erase state is determined. When the sub-block SB1 is in the entire erase state, the procedure proceeds to Step S202, and when the sub-block SB1 is not in the entire erase state, the procedure proceeds to Step S205. Step S201 is performed, for example, similarly to Step S121 (FIG. 20).

At Step S202, whether or not the sub-block SB0 is in the partial write state is determined. When the sub-block SB0 is in the partial write state, the procedure proceeds to Step S203, and when the sub-block SB0 is in an entire write state, the procedure proceeds to Step S204. An operation to determine whether or not the sub-block SB0 is in the partial write state is described later.

At Step S203, pre-programming of the sub-block SB0 described later is performed, and the procedure proceeds to Step S204.

At Step S204, the sub-block SB0 erase operation is performed. Step S204 is performed, for example, similarly to Step S122 (FIG. 20).

At Step S205, whether or not the sub-block SB1 is in the partial write state is determined. When the sub-block SB1 is in the partial write state, the procedure proceeds to Step S206, and when the sub-block SB1 is in the entire write state, the procedure proceeds to Step S207. An operation to determine whether or not the sub-block SB1 is in the partial write state is described later.

At Step S206, pre-programming of the sub-block SB1 described later is performed, and the procedure proceeds to Step S207.

At Step S207, the memory block erase operation (FIG. 16) is performed.

### [Operation to Determine Whether or not Sub-Block SB0 is in Partial Write State]

FIG. 31 to FIG. 34 are schematic diagrams illustrating examples of the write status of the sub-block.

This operation is, for example, one of operations performed inside the memory die MD when a command instructing the erase operation on the selected memory block BLK is transmitted to the memory die MD.

Before this operation, for example, the read operation is performed on the page PG_UF (1) (Step S201). This operation is performed when the page PG_UF (1) is in the erase state Er.

In this operation, for example, as illustrated in FIG. 31, the read operation is performed on a page PG_LE (2) on which the write operation is performed last among the pages PG in the sub-block SB0. In the example illustrated in FIG. 31, the page PG_LE (2) is a page PG corresponding to the word line WL47 and the string unit SU3 in the sub-block SB0.

FIG. 31 illustrates a case where the sub-block SB1 is in the entire erase state and the sub-block SB0 in the partial write state. In this case, when a result that the page PG_LE (2) is in the erase state Er is obtained by the read operation, the sub-block SB0 can be determined to be in the partial write state as illustrated in FIG. 31.

### [Operation to Determine Whether or not Sub-Block SB1 is in Partial Write State]

This operation is, for example, one of operations performed inside the memory die MD when a command instructing the erase operation on the selected memory block BLK is transmitted to the memory die MD.

Before this operation, for example, the read operation is performed on the page PG_UF (1) (Step S201). This operation is performed when the page PG_UF (1) is in the write state Pg.

In this operation, for example, as illustrated in FIG. 32, the read operation is performed on a page PG_UE (2) on which the write operation is performed last among the pages PG in the sub-block SB1. In the example illustrated in FIG. 32, the page PG_UE (2) is a page PG corresponding to the word line WL95 and the string unit SU3 in the sub-block SB1.

FIG. 32 illustrates a case where the sub-block SB1 is in the partial write state. When a result that the page PG_UE (2) is in the erase state Er is obtained by the read operation, the sub-block SB1 can be determined to be in the partial write state as illustrated in FIG. 32.

### [Pre-Programming of Sub-Blocks SB0, SB1]

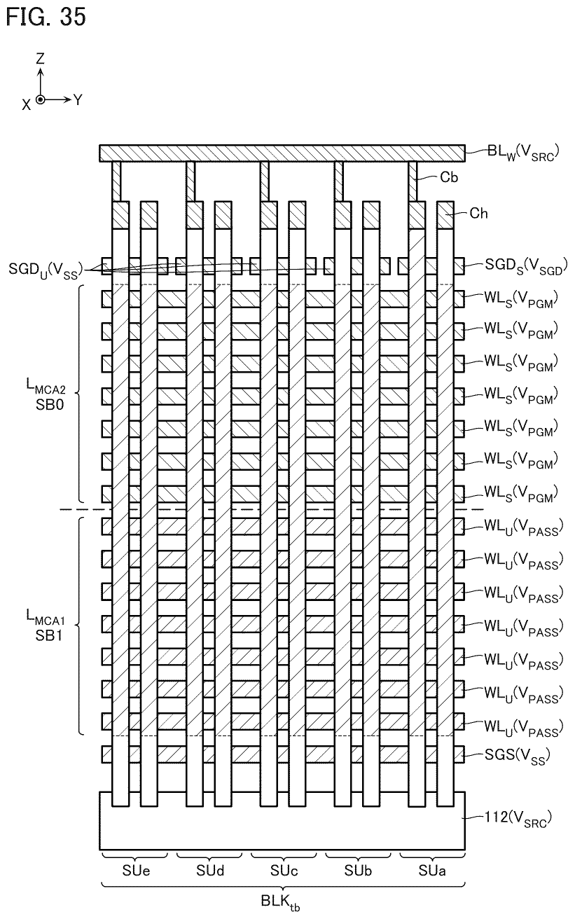

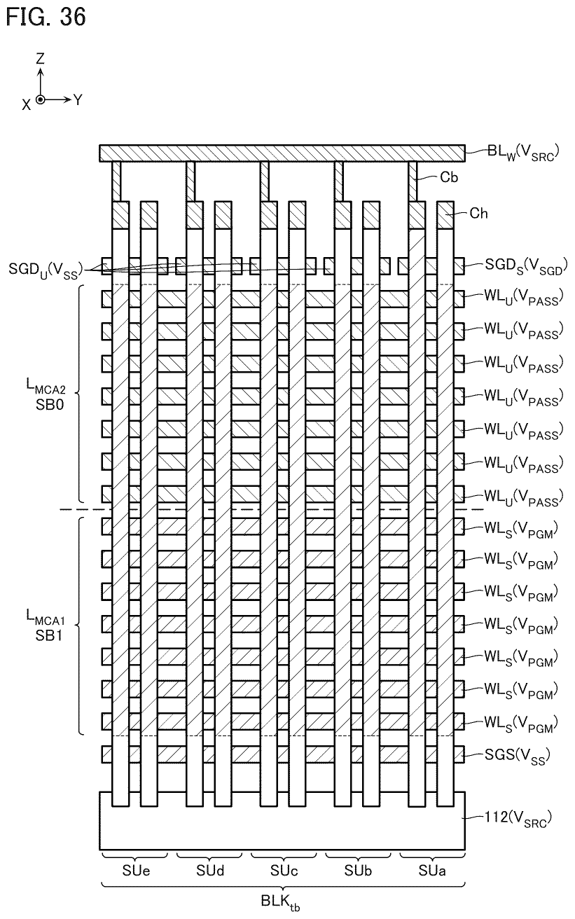

FIG. 35 and FIG. 36 are schematic cross-sectional views for describing pre-programming of the sub-blocks SB0, SB1.

The pre-programming of the sub-blocks SB0, SB1 is basically performed similarly to the write operation (FIG. 13 to FIG. 15).

However, in the pre-programming of the sub-block SB0, in the program operation at Step S102 (FIG. 13), for example, as illustrated in FIG. 35, all the word lines WL of the sub-block SB0 are the selected word lines WL_{S}, and all the word lines WL of the sub-block SB1 are the unselected word lines WL_{U}. Thus, the program voltage V_{PGM} is applied to the word line WL of the sub-block SB0 (FIG. 35), and the threshold voltage of the write memory cell MC included in the sub-block SB0 increases.

In the pre-programming of the sub-block SB1, in the program operation at Step S102 (FIG. 13), for example, as illustrated in FIG. 36, all the word lines WL of the sub-block SB1 are the selected word lines WL_{S}, and all the word lines WL of the sub-block SB0 are the unselected word lines WL_{U}. Thus, the program voltage V_{PGM} is applied to the word line WL of the sub-block SB1 (FIG. 36), and the threshold voltage of the write memory cell MC included in the sub-block SB1 increases.

These operations of pre-programming may be performed for each string unit SU (FIG. 35 and FIG. 36), and may be simultaneously performed on a plurality of string units SU.

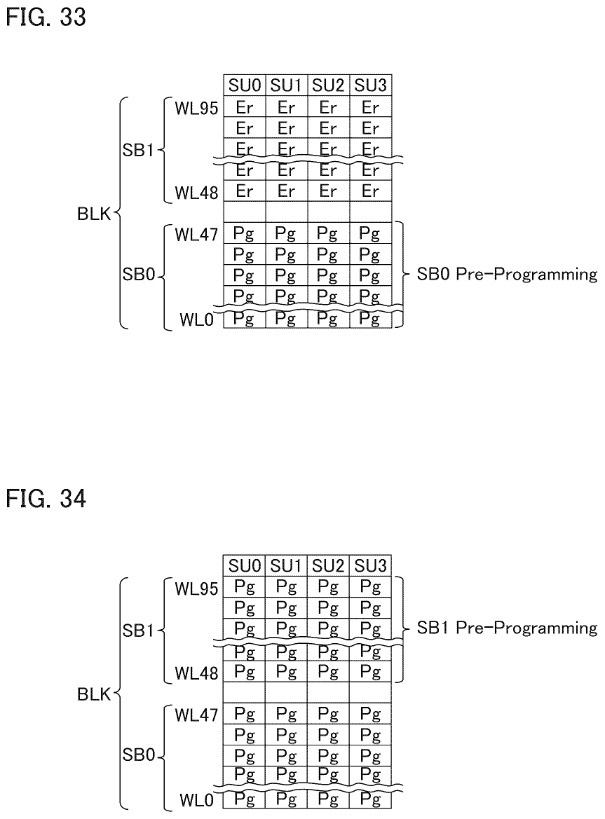

By performing the pre-programming on the sub-block SB0 as illustrated in FIG. 31, the sub-block SB0 becomes in the entire write state as illustrated in FIG. 33. By performing the pre-programming on the sub-block SB1 as illustrated in FIG. 32, the sub-block SB1 becomes in the entire write state as illustrated in FIG. 34.

In the pre-programming of the sub-blocks SB0, SB1, Steps S103 to S108 (FIG. 13) relating to the verify operation do not need to be performed.

In the pre-programming of the sub-blocks SB0, SB1, a period of applying the program voltage V_{PGM} to the selected word line WL_{S} (timings t113 to t114) may be longer than that in the example illustrated in FIG. 14.

### [Operation Example of Select Erase Operation (2)]

An operation when the sub-block SB1 is in the entire erase state, and the sub-block SB0 is in the partial write state (FIG. 31) is referred to as an operation example EX20. In the operation example EX20, after the sub-block SB0 is turned to the entire write state (FIG. 33) by the pre-programming at Step S203 (FIG. 30), the erase operation of the sub-block SB0 at Step S204 is performed, thereby turning all the pages PG to the erase state Er (FIG. 23).

An operation when the sub-block SB1 is in the entire erase state, and the sub-block SB0 is in the entire write state is referred to as an operation example EX21. In the operation example EX21, Step S203 (FIG. 30) is skipped, and the sub-block SB0 erase operation at Step S204 is performed, thereby turning all the pages PG to the erase state Er (FIG. 23).

An operation when the sub-block SB1 is in the partial write state (FIG. 32) is referred to as an operation example EX22. In the operation example EX22, after turning the sub-block SB1 to the entire write state (FIG. 34) by the pre-programming at Step S206 (FIG. 30), the memory block erase operation at Step S207 is performed, thereby turning all the pages PG to the erase state Er (FIG. 23).

An operation when the sub-block SB1 is in the entire write state is referred to as an operation example EX23. In the operation example EX23, Step S206 (FIG. 30) is skipped, and the memory block erase operation at Step S207 is performed, thereby turning all the pages PG to the erase state Er (FIG. 23).

### Effects

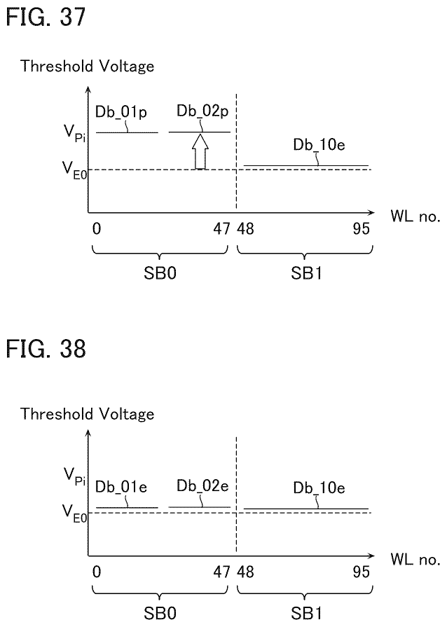

FIG. 37 and FIG. 38 are graphs for describing the semiconductor memory device according to the embodiment. FIG. 37 and FIG. 38 indicate medians of the threshold voltages of a plurality of memory cells MC in the pages PG corresponding to the respective word lines WL having the word lines WL0 to WL95 as the horizontal axis.

FIG. 37 is a diagram when the pre-programming is performed on the sub-block SB0 corresponding to FIG. 31. By the pre-programming, the pages PG corresponding to a plurality of word lines WL positioned on the other side of the sub-block SB0 turn from the erase state Er to the write state Pg, and the median of the threshold voltage increases to, for example, approximately the voltage V_{Pi} (group Db_02p in FIG. 37).

FIG. 38 is a diagram when the sub-block SB0 erase operation is performed after the pre-programming of the sub-block SB0 (FIG. 37). Since there is no page PG in the erase state Er in the sub-block SB0 after the pre-programming, as illustrated in FIG. 38, the sub-block SB0 erase operation does not cause the over erase state of the memory cell MC in the sub-block SB0.

In the operation examples EX20, EX21, since the erase operation is performed only on the sub-block SB0 at Step S204, the over erase state of the memory cell MC included in the sub-block SB1 can be avoided.

In the operation examples EX20, EX22, the pre-programming at Steps S203, S206 allows a part of the pages PG in the erase state Er included in the sub-blocks SB0, SB1 to avoid becoming in the over erase state.

In the operation example EX21, EX23, by skipping the pre-programming at Steps S203, S206, occurrence of write stress on the memory cell MC due to unnecessary pre-programming can be avoided.

### Modification of Second Embodiment

In a semiconductor memory device according to the modification, a controller die CD includes a register RG or the like possible to store the erase state and the write state for each sub-block.

At Step S201 (FIG. 30) of this modification, the controller determines whether or not the sub-block SB1 is in the entire erase state by referring to the register RG and the like.

At Steps S202, S205 (FIG. 30) of this modification, the controller determines whether or not the sub-blocks SB0, SB1 are in the partial write state by referring to the register RG and the like.

At Steps S203, S206 (FIG. 30) of this modification, the controller transmits the respective commands instructing the pre-programming of the sub-blocks SB0, SB1 to the memory die MD, and the memory die MD executes the pre-programming of the respective sub-blocks SB0, SB1.

At Step S204 (FIG. 30) of this modification, the controller transmits the command instructing the sub-block SB0 erase operation to the memory die MD, and the memory die MD executes the sub-block SB0 erase operation.

At Step S207 (FIG. 30) of this modification, the controller transmits the command instructing the memory block erase operation to the memory die MD, and the memory die MD executes the memory block erase operation (FIG. 16).

### Third Embodiment

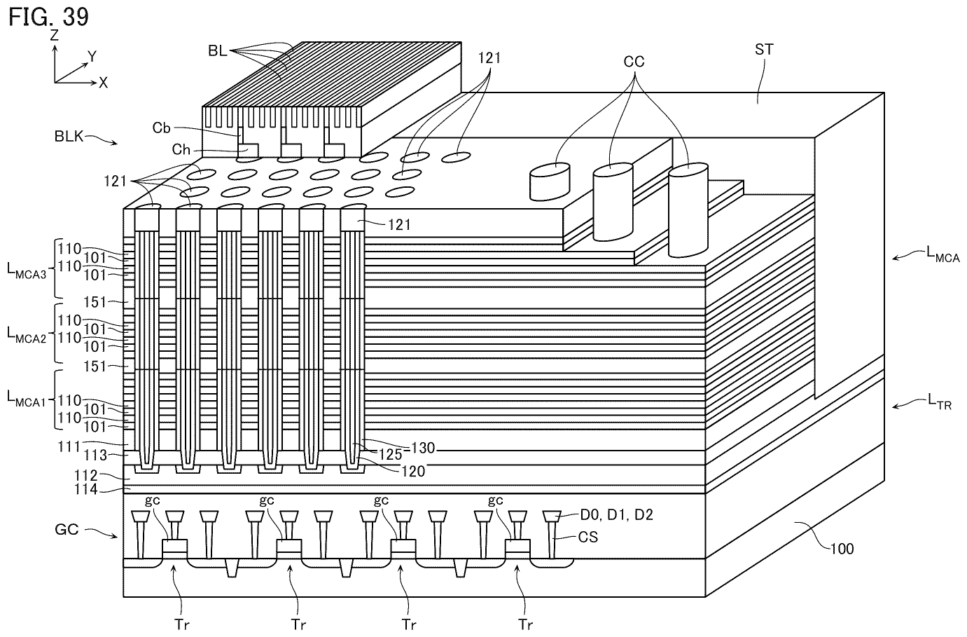

Next, a semiconductor memory device according to a third embodiment is described. FIG. 39 is a schematic perspective view illustrating a configuration of a part of the semiconductor memory device according to the third embodiment. In the following description, for configurations and operations similar to those of the first embodiment, the explanation may be omitted.

The semiconductor memory device according to the embodiment is basically configured similarly to the semiconductor memory device according to the first embodiment. However, for example, as illustrated in FIG. 39, in the semiconductor memory device according to the embodiment, a memory block BLK further includes a memory cell array layer L_{MCA3} disposed above a memory cell array layer L_{MCA2}.

The memory cell array layer L_{MCA3} is basically disposed similarly to the memory cell array layer L_{MCA1} and the memory cell array layer L_{MCA2}. The memory cell array layer L_{MCA3} includes, for example, a plurality of conductive layers 110 arranged in the Z-direction, a plurality of semiconductor layers 120 extending in the Z-direction, and a plurality of gate insulating films 130 each disposed between the plurality of conductive layers 110 and the plurality of semiconductor layers 120. Between the memory cell array layer L_{MCA3} and the memory cell array layer L_{MCA2}, an insulating layer 151 of silicon oxide (SiO₂) or the like is disposed.

The semiconductor memory device according to the embodiment is configured to be able to perform a select erase operation (3).

### [Select Erase Operation (3)]

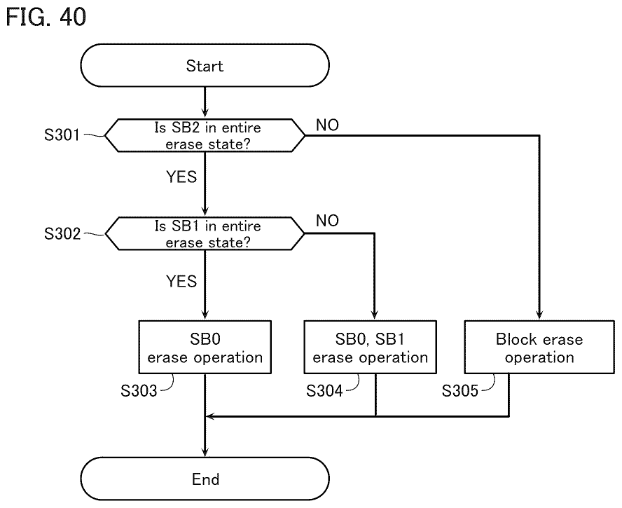

FIG. 40 is a flowchart for describing the select erase operation (3).

In an example below, in the memory block BLK, the write operation is performed on the sub-block SB0 first, and subsequently, the write operation is sequentially performed on the sub-block SB1, and then sub-block SB2.

At Step S301, whether or not the sub-block SB2 is in the entire erase state is determined. When the sub-block SB2 is in the entire erase state, the procedure proceeds to Step S302, and when the sub-block SB2 is not in the entire erase state, the procedure proceeds to Step S305. The operation to determine whether or not the sub-block SB2 is in the entire erase state is described later.

At Step S302, whether or not the sub-block SB1 is in the entire erase state is determined. When the sub-block SB1 is in the entire erase state, the procedure proceeds to Step S303, and when the sub-block SB1 is not in the entire erase state, the procedure proceeds to Step S304. Step S302 is performed, for example, similarly to Step S121 (FIG. 20).

At Step S303, the sub-block SB0 erase operation is performed. At Step S303, an operation similar to that of Step S122 (FIG. 20) is basically performed. However, in this operation, an unselect erase voltage V_{X} similar to that of the sub-block SB1 is applied to the word line WL of the sub-block SB2 as well.

At Step S304, the sub-blocks SB0, SB1 erase operation is performed. At Step S304, an operation similar to that of Step S122 (FIG. 20) is basically performed. However, at timing t132 (FIG. 24) in this operation, the ground voltage V_{SS} is applied to the word lines WL of the sub-blocks SB0, SB1, and the unselect erase voltage V_{X} is applied to the word line WL of the sub-block SB2. Accordingly, the erase of the memory cell MC included in the sub-block SB2 is not performed.

At Step S305, an operation similar to that of the memory block erase operation (FIG. 16) is basically performed. However, at timing t122 (FIG. 17) of this operation, the ground voltage V_{SS} similar to that applied to the word lines WL of the sub-blocks SB0, SB1 is applied to the word line WL of the sub-block SB2 as well.

### [Operation to Determine Whether or not Sub-Blocks SB1, SB2 are in Entire Erase State]

FIG. 41 to FIG. 44 are schematic diagrams illustrating examples of a write status of the sub-block.

This operation is, for example, one of operations performed inside the memory die MD when a command instructing the erase operation on the selected memory block BLK is transmitted to the memory die MD.

In the examples illustrated in FIG. 41 to FIG. 44 and FIG. 46 to FIG. 51, the 144 layers of the word lines WL are disposed in total, and the m-th (m is an integer of 1 to 144) word line WL counted from the lowermost layer is indicated as a word line WL (m−1). In the examples of FIG. 41 to FIG. 44, the sub-block SB0 includes the word lines WL0 to WL47, the sub-block SB1 includes the word lines WL48 to WL95, and the sub-block SB2 includes the word lines WL96 to WL143.

In the examples illustrated in FIG. 41 to FIG. 44 and FIG. 46 to FIG. 51, the write operation is performed on from the word line WL0 to the word line WL143 in ascending order of m of the word line WL (m−1), and in each of the word lines WL, the write operation is performed in the order of the string units SU0, SU1, SU2, and SU3.

In this operation, for example, as illustrated in FIG. 41 to FIG. 43, the read operation is performed on a page PG_TF (1) on which the write operation is performed first among the pages PG in the sub-block SB2. In the examples illustrated in FIG. 41 to FIG. 43, the page PG_TF (1) is a page PG corresponding to the word line WL96 and the string unit SU0 in the sub-block SB2.

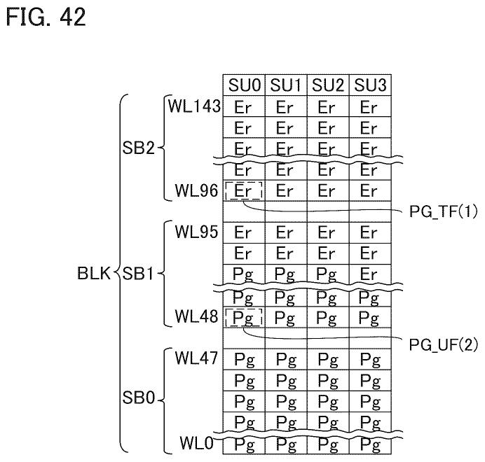

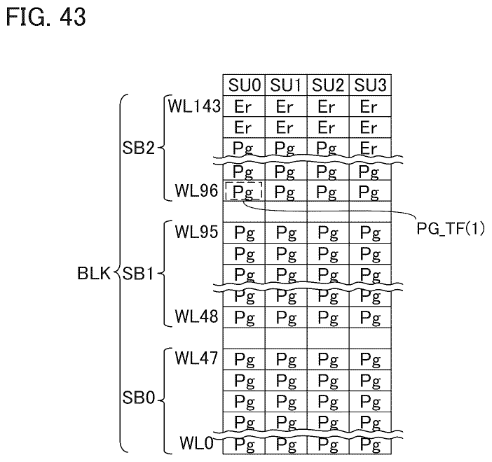

FIG. 41 and FIG. 42 illustrate the case where the sub-block SB2 is in the entire erase state. FIG. 43 illustrates the case where the sub-block SB2 is not in the entire erase state. When the page PG_TF (1) is in the erase state Er, the sub-block SB2 can be determined to be in the entire erase state (FIG. 41 and FIG. 42), and when the page PG_TF (1) is in the write state Pg, the sub-block SB2 can be determined to be not in the entire erase state (FIG. 43).

When the page PG_TF (1) is in the erase state Er, at Step S302 (FIG. 40), the read operation is performed on a page PG_UF (2) on which the write operation is performed first among the pages PG in the sub-block SB1. In the examples illustrated in FIG. 41 and FIG. 42, the page PG_UF (2) is a page PG corresponding to the word line WL48 and the string unit SU0 in the sub-block SB1.

FIG. 41 illustrates the case where the sub-block SB1 is in the entire erase state. FIG. 42 illustrates the case where the sub-block SB1 is not in the entire erase state. When the page PG_UF (2) is in the erase state Er, the sub-block SB1 can be determined to be in the entire erase state (FIG. 41), and when the page PG_UF (2) is in the write state Pg, the sub-block SB1 can be determined to be not in the entire erase state (FIG. 42).

### [Operation Example of Select Erase Operation (3)]

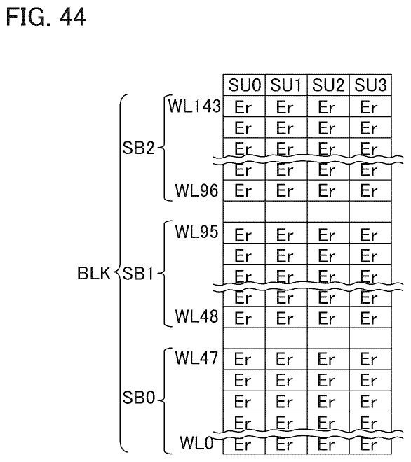

An operation when the sub-blocks SB1, SB2 are in the entire erase state (FIG. 41) is referred to as an operation example EX30. In the operation example EX30, the sub-block SB0 erase operation at Step S303 is performed, thereby turning all the pages PG included in the memory block BLK to the erase state Er as illustrated in FIG. 44.

An operation when only the sub-block SB2 is in the entire erase state (FIG. 42) is referred to as an operation example EX31. In the operation example EX31, the erase operation is performed on the sub-blocks SB0, SB1 at Step S304, thereby turning all the pages PG included in the memory block BLK to the erase state Er as illustrated in FIG. 44.

An operation when any of the sub-blocks SB0, SB1, SB2 is not in the entire erase state (FIG. 43) is referred to as an operation example EX32. In the operation example EX32, the memory block erase operation at Step S305 is performed, thereby turning all the pages PG included in the memory block BLK to the erase state Er as illustrated in FIG. 44.

### Effects

In the operation example EX30, since the erase operation is performed only on the sub-block SB0 at Step S303, the over erase state of the memory cell MC included in the sub-blocks SB1, SB2 can be avoided.

In the operation example EX31, since the erase operation is performed only on the sub-blocks SB0, SB1 at Step S304, the over erase state of the memory cell MC included in the sub-block SB2 can be avoided.

### Modification of Third Embodiment

In a semiconductor memory device according to the modification, a controller die CD includes a register RG or the like possible to store the erase state and the write state for each sub-block.

At Steps S301, S302 of this modification, the controller determines whether or not the sub-blocks SB2, SB1 are in the entire erase state by referring to the register RG and the like.

At Step S303 of this modification, the controller transmits the command instructing the sub-block SB0 erase operation to the memory die MD, and the memory die MD executes the sub-block SB0 erase operation.

At Step S304 of this modification, the controller transmits the command instructing the sub-blocks SB0, SB1 erase operation to the memory die MD, and the memory die MD executes the sub-blocks SB0, SB1 erase operation.

At Step S305 of this modification, the controller transmits the command instructing the memory block erase operation to the memory die MD, and the memory die MD executes the memory block erase operation (FIG. 16).

### Fourth Embodiment

Next, a semiconductor memory device according to a fourth embodiment is described. In the following description, for configurations and operations similar to those of the first embodiment to the third embodiment, the explanation may be omitted.

The semiconductor memory device according to the embodiment is basically configured similarly to the semiconductor memory device according to the third embodiment. However, the semiconductor memory device according to the embodiment is configured to be able to perform a select erase operation (4).

### [Select Erase Operation (4)]

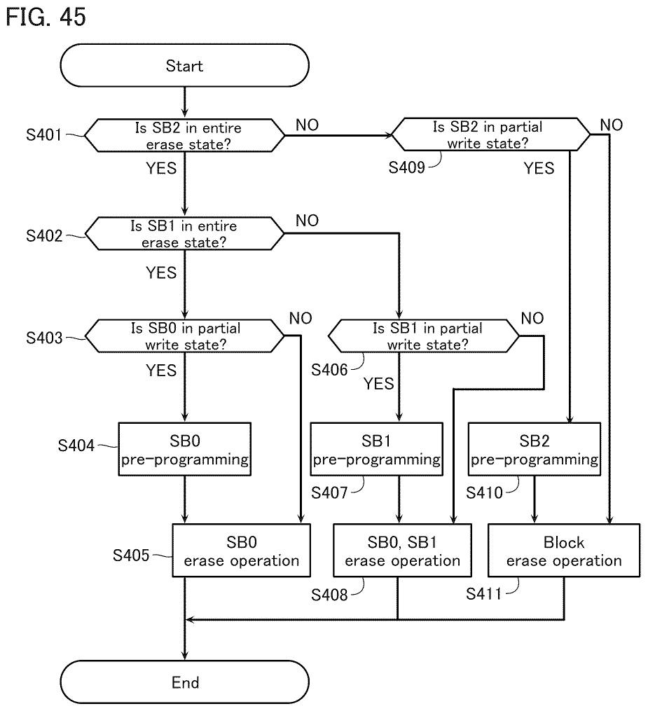

FIG. 45 is a flowchart for describing the select erase operation (4). FIG. 46 to FIG. 51 are schematic diagrams illustrating examples of the write status of the sub-block.

In an example below, in the memory block BLK, the write operation is performed on the sub-block SB0 first, and subsequently, the write operation is sequentially performed on the sub-block SB1, and then sub-block SB2.

At Step S401, whether or not the sub-block SB2 is in the entire erase state is determined. When the sub-block SB2 is in the entire erase state, the procedure proceeds to Step S402, and when the sub-block SB2 is not in the entire erase state, the procedure proceeds to Step S409. Step S401 is performed, for example, similarly to Step S301 (FIG. 40).

At Step S402, whether or not the sub-block SB1 is in the entire erase state is determined. When the sub-block SB1 is in the entire erase state, the procedure proceeds to Step S403, and when the sub-block SB1 is not in the entire erase state, the procedure proceeds to Step S406. Step S402 is performed, for example, similarly to Step S302 (FIG. 40).

At Step S403, whether or not the sub-block SB0 is in the partial write state is determined. When the sub-block SB0 is in the partial write state, the procedure proceeds to Step S404, and when the sub-block SB0 is in the entire write state, the procedure proceeds to Step S405. At Step S403, the determination is made by performing the read operation on a page PG_LE (3) (FIG. 46) on which the write operation is performed last among the pages PG in the sub-block SB0.

At Step S404, pre-programming of the sub-block SB0 is performed, and the procedure proceeds to Step S405. Step S404 is basically performed similarly to Step S203 (FIG. 30). However, Step S404 is performed with the word line WL of the sub-block SB0 as the selected word line WL_{S} and the word lines WL of the sub-blocks SB1, SB2 as the unselected word lines WL_{U} in the program operation at Step S102 (FIG. 13).

At Step S405, the sub-block SB0 erase operation is performed. Step S405 is performed similarly to Step S303 (FIG. 40).

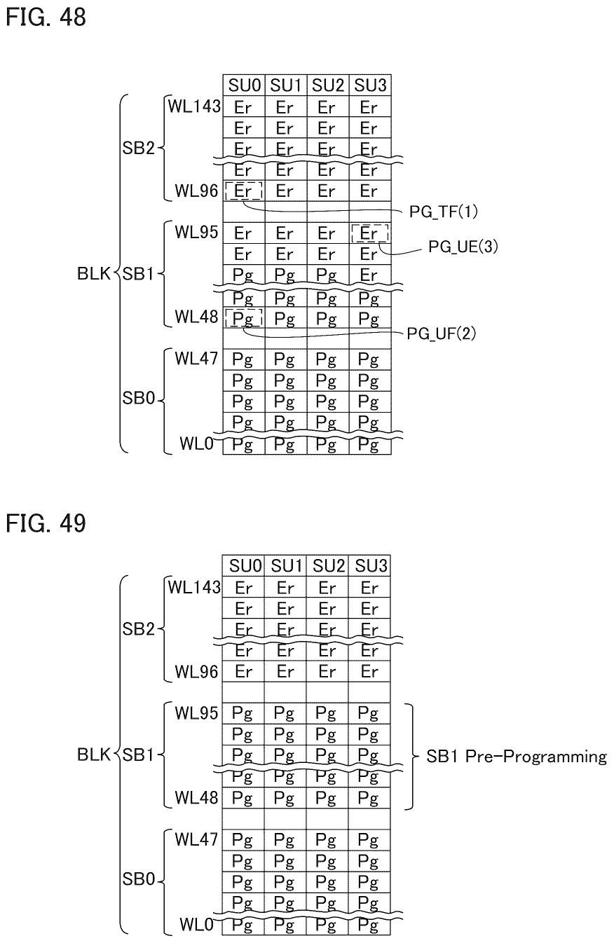

At Step S406, whether or not the sub-block SB1 is in the partial write state is determined. When the sub-block SB1 is in the partial write state, the procedure proceeds to Step S407, and when the sub-block SB1 is in the entire write state, the procedure proceeds to Step S408. At Step S406, the determination is made by performing the read operation on a page PG_UE (3) (FIG. 48) on which the write operation is performed last among the pages PG in the sub-block SB1.

At Step S407, pre-programming of the sub-block SB1 is performed, and the procedure proceeds to Step S408. Step S407 is basically performed similarly to Step S206 (FIG. 30). However, Step S407 is performed with the word line WL of the sub-block SB1 as the selected word line WL_{S} and the word lines WL of the sub-blocks SB0, SB2 as the unselected word lines WL_{U}.

At Step S408, the sub-blocks SB0, SB1 erase operation is performed. Step S408 is performed, for example, similarly to Step S304 (FIG. 40).

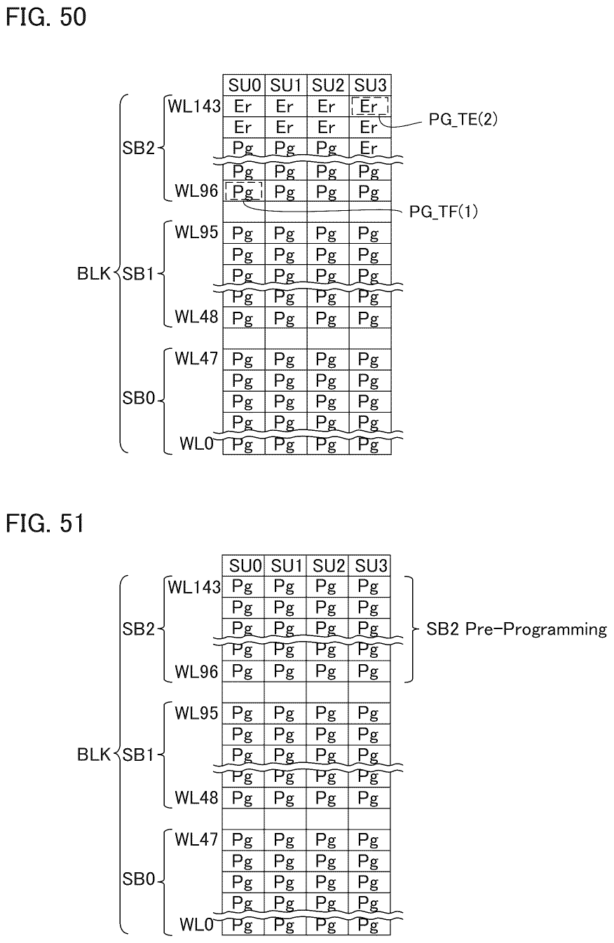

At Step S409, whether or not the sub-block SB2 is in the partial write state is determined. When the sub-block SB2 is in the partial write state, the procedure proceeds to Step S410, and when the sub-block SB2 is in the entire write state, the procedure proceeds to Step S411. At Step S409, the determination is made by performing the read operation on a page PG_TE (2) (FIG. 50) on which the write operation is performed last among the pages PG in the sub-block SB2.

At Step S410, pre-programming of the sub-block SB2 is performed, and the procedure proceeds to Step S411. Step S410 is basically performed similarly to Step S407 (FIG. 45). However, Step S410 is performed with the word line WL of the sub-block SB2 as the selected word line WL_{S} and the word lines WL of the sub-blocks SB0, SB1 as the unselected word lines WL_{U}.

At Step S411, the memory block erase operation (FIG. 16) is performed.

### [Operation Example of Select Erase Operation (4)]

An operation when the sub-blocks SB1, SB2 are in the entire erase state, and the sub-block SB0 is in the partial write state (FIG. 46) is referred to as an operation example EX40. In the operation example EX40, at Steps S401, S402, S403, the read operation is performed on the pages PG_TF (1), PG_UF (2), PG_LE (3), respectively. Further, in the operation example EX40, after turning the sub-block SB0 to the entire write state (FIG. 47) at Step S404 (FIG. 45), the sub-block SB0 erase operation is performed at Step S405, thereby turning all the pages PG to the erase state Er (FIG. 44).

An operation when the sub-blocks SB1, SB2 are in the entire erase state, and the sub-block SB0 is in the entire write state is referred to as an operation example EX41. While the operation example EX41 is basically similar to the operation example EX40, Step S404 (FIG. 45) is skipped in the operation example EX41.

An operation when the sub-block SB2 is in the entire erase state, and the sub-block SB1 is in the partial write state (FIG. 48) is referred to as an operation example EX42. In the operation example EX42, at Steps S401, S402, S406, the read operation is performed on the pages PG_TF (1), PG_UF (2), PG_UE (3), respectively. Further, in the operation example EX42, after turning the sub-block SB1 to the entire write state (FIG. 49) at Step S407 (FIG. 45), the sub-blocks SB0, SB1 erase operation is performed at Step S408, thereby turning all the pages PG to the erase state Er (FIG. 44).

An operation when the sub-block SB2 is in the entire erase state, and the sub-block SB1 is in the entire write state is referred to as an operation example EX43. While the operation example EX43 is basically similar to the operation example EX42, Step S407 (FIG. 45) is skipped in the operation example EX43.

An operation when the sub-block SB2 is in the partial write state (FIG. 50) is referred to as an operation example EX44. In the operation example EX44, at Steps S401, S409, the read operation is performed on the pages PG_TF (1), PG_TE (2), respectively. Further, in the operation example EX44, after turning the sub-block SB2 to the entire write state (FIG. 51) at Step S410 (FIG. 45), the memory block BLK erase operation is performed at Step S411, thereby turning all the pages PG to the erase state Er (FIG. 44).

An operation when the sub-block SB2 is in the entire write state is referred to as an operation example EX45. While the operation example EX45 is basically similar to the operation example EX44, Step S410 (FIG. 45) is skipped in the operation example EX45.

### Effects

In the operation examples EX40, EX41, since the erase operation is performed only on the sub-block SB0 at Step S405, the over erase state of the memory cell MC included in the sub-blocks SB1, SB2 can be avoided.

In the operation examples EX42, EX43, since the erase operation is performed only on the sub-blocks SB0, SB1 at Step S408, the over erase state of the memory cell MC included in the sub-block SB2 can be avoided.

In the operation examples EX40, EX42, EX44, the pre-programming at Steps S404, S407, S410 allows a part of the pages PG in the erase state Er included in the sub-blocks SB0, SB1, SB2 to avoid becoming in the over erase state.

In the operation examples EX41, EX43, EX45, by skipping the pre-programming at Steps S404, S407, S410, occurrence of write stress on the memory cell MC due to unnecessary pre-programming can be avoided.

### Modification of Fourth Embodiment

In a semiconductor memory device according to the modification, a controller die CD includes a register RG or the like possible to store the erase state and the write state for each sub-block.

At Steps S401, S402 of this modification, the controller determines whether or not the sub-blocks SB2, SB1 are in the entire erase state by referring to the register RG and the like.

At Steps S403, S406, S409 of this modification, the controller determines whether or not the sub-blocks SB0, SB1, SB2 are in the partial write state by referring to the register RG and the like.

At Steps S404, S407, S410 of this modification, the controller transmits the respective commands instructing the pre-programming of the sub-blocks SB0, SB1, SB2 to the memory die MD, and the memory die MD executes the pre-programming of the respective sub-blocks SB0, SB1, SB2.

At Step S405 of this modification, the controller transmits the command instructing the sub-block SB0 erase operation to the memory die MD, and the memory die MD executes the sub-block SB0 erase operation.

At Step S408 of this modification, the controller transmits the command instructing the sub-blocks SB0, SB1 erase operation to the memory die MD, and the memory die MD executes the sub-blocks SB0, SB1 erase operation.

At Step S411 of this modification, the controller transmits the command instructing the memory block erase operation to the memory die MD, and the memory die MD executes the memory block erase operation (FIG. 16).

### Fifth Embodiment

Next, a semiconductor memory device according to a fifth embodiment is described. In the following description, for configurations and operations similar to those of the first embodiment to the fourth embodiment, the explanation may be omitted.

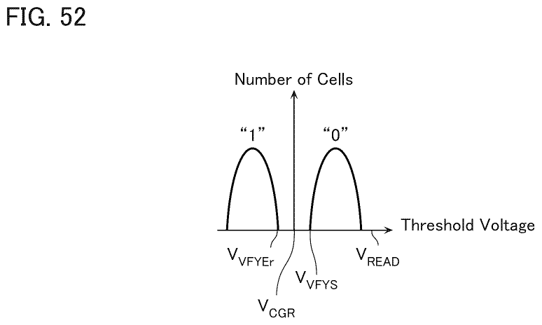

The semiconductor memory device according to the embodiment is basically configured similarly to the semiconductor memory device according to the second embodiment. However, the semiconductor memory device according to the embodiment includes a case where 3-bit data is stored in the memory cell MC (FIG. 10A to FIG. 10C) and a case where 1-bit data is stored in the memory cell MC (FIG. 52). Hereinafter, the case of storing 3-bit data may be referred to as a 3-bit mode, and the case of storing 1-bit data may be referred to as a 1-bit mode.

[Threshold Voltage of Memory Cell MC that Stores 1-Bit Data]

FIG. 52 is a schematic histogram for describing the threshold voltage of the memory cell MC that stores 1-bit data. The horizontal axis indicates the voltage of the word line WL, and the vertical axis indicates the number of the memory cells MC.

In the example of FIG. 52, the threshold voltage of the memory cell MC is controlled to two states. For example, the threshold voltage of the memory cell MC controlled in the lower state is smaller than the erase verify voltage V_{VFYEr}. The threshold voltage of the memory cell MC controlled in the upper state is larger than the verify voltage V_{VFYs} and smaller than a read pass voltage V_{READ_S}.

In the example of FIG. 52, the read voltage V_{CGR} is set between the threshold distribution corresponding to the lower state and the threshold distribution corresponding to the upper state.

For example, the lower state corresponds to a low threshold voltage. The memory cell MC in the lower state is, for example, a memory cell MC in the erase state. For example, data “1” is assigned to the memory cell MC in the lower state.

The upper state corresponds to a high threshold voltage. The memory cell MC in the upper state is, for example, a memory cell MC in the write state. For example, data “0” is assigned to the memory cell MC in the upper state.

The semiconductor memory device according to the embodiment is configured to be able to perform a select erase operation (5).

### [Select Erase Operation (5)]

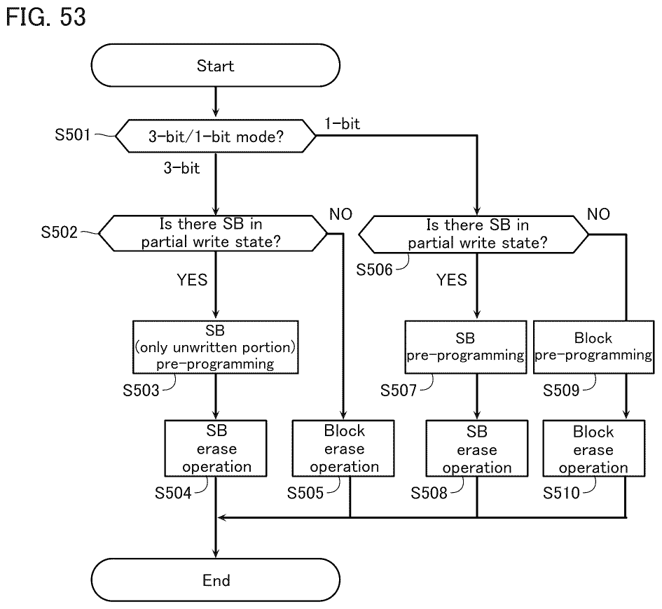

FIG. 53 is a flowchart for describing the select erase operation (5). FIG. 54 to FIG. 57 are schematic diagrams illustrating examples of the write status of the sub-block.

FIG. 54 to FIG. 57 illustrate the write statuses of the pages PG corresponding to a plurality of word lines WL and four string units SU0, SU1, SU2, SU3 disposed in the memory block BLK. The write status of the page PG is indicated as any of a write state Pgs in which 1-bit data is stored, a write state Pgt in which 3-bit data is stored, a write state Pg after the pre-programming, and an erase state Er.

In the examples illustrated in FIG. 54 to FIG. 57, in the memory block BLK, the write operation is performed on the sub-block SB0 first, and subsequently, the write operation is performed on the sub-block SB1. Further, the write operation is performed on from the word line WL0 to the word line WL95 in ascending order of n of the word line WL (n−1), and in each of the word lines WL, the write operation is performed in the order of the string units SU0, SU1, SU2, and SU3.

At Step S501, when a selected memory block BLK stores 3-bit data, the procedure proceeds to Step S502, and when the selected memory block BLK stores 1-bit data, the procedure proceeds to Step S506. At Step S501, for example, the controller makes determination by referring to information on the selected memory block BLK held in the register RG or the like.

At Step S502, whether or not there are sub-blocks SB0, SB1 in the partial write state is determined. When there is the sub-block SB0, SB1 in the partial write state, the procedure proceeds to Step S503, and when there is no sub-block SB0, SB1 in the partial write state (sub-blocks SB0, SB1 are in the entire write state), the procedure proceeds to Step S505. At Step S502, for example, the controller makes determination by referring to information on the sub-blocks SB0, SB1 held in the register RG or the like.

At Step S503, pre-programming is performed on the sub-blocks SB0, SB1 in the partial write state, and the procedure proceeds to Step S504. At Step S503, pages PG in the erase state Er (unwritten pages) included in the sub-block SB0, SB1 in the partial write state (in the example of FIG. 54, sub-block SB0) are sequentially selected, and the pre-programming is performed on only the pages PG in the erase state Er to turn them in the write state Pg (FIG. 55).

At Step S504, the sub-block erase operation is performed on the sub-block (in the example of FIG. 55, sub-block SB0) on which the pre-programming has been performed at Step S503.

At Step S505, the memory block erase operation (FIG. 16) is performed.

At Step S506, whether or not there are sub-blocks SB0, SB1 in the partial write state is determined. When there is the sub-block SB0, SB1 in the partial write state, the procedure proceeds to Step S507, and when there is no sub-block SB0, SB1 in the partial write state, the procedure proceeds to Step S509. At Step S506, for example, the controller makes determination by referring to information on the sub-blocks SB0, SB1 held in the register RG or the like.

At Step S507, pre-programming is performed on the sub-blocks SB0, SB1 in the partial write state, and the procedure proceeds to Step S508. Step S507 is performed, for example, similarly to Steps S203, S206 (FIG. 30).

At Step S508, the sub-block erase operation is performed on the sub-block (in the example of FIG. 57, sub-block SB0) on which the pre-programming has been performed at Step S507.

At Step S509, block pre-programming is performed on the memory block BLK. The block pre-programming is basically performed similarly to the pre-programming. However, the block pre-programming is performed with the word lines WL of the sub-blocks SB0, SB1 as the selected word lines WL_{S} in the program operation at Step S102 (FIG. 13).

At Step S510, the memory block erase operation (FIG. 16) is performed.

### [Operation Example of Select Erase Operation (5)]

An operation when the sub-block SB1 is in the entire erase state, and the sub-block SB0 is in the partial write state in the 3-bit mode (FIG. 54) is referred to as an operation example EX50. In the operation example EX50, the pre-programming is performed only on the unwritten page at Step S503, thereby turning the pages PG in the erase state Er of the sub-block SB0 (FIG. 54) to the write state Pg (FIG. 55). Next, the erase operation is performed on the sub-block SB0 at Step S504, thereby turning all the pages PG included in the memory block BLK to the erase state Er (FIG. 23).

An operation when the sub-blocks SB0, SB1 are in the entire write state in the 3-bit mode is referred to as an operation example EX51. In the operation example EX51, Step S503 is skipped, and the memory block erase operation is performed at Step S505, thereby turning all the pages PG included in the memory block BLK to the erase state Er (FIG. 23).

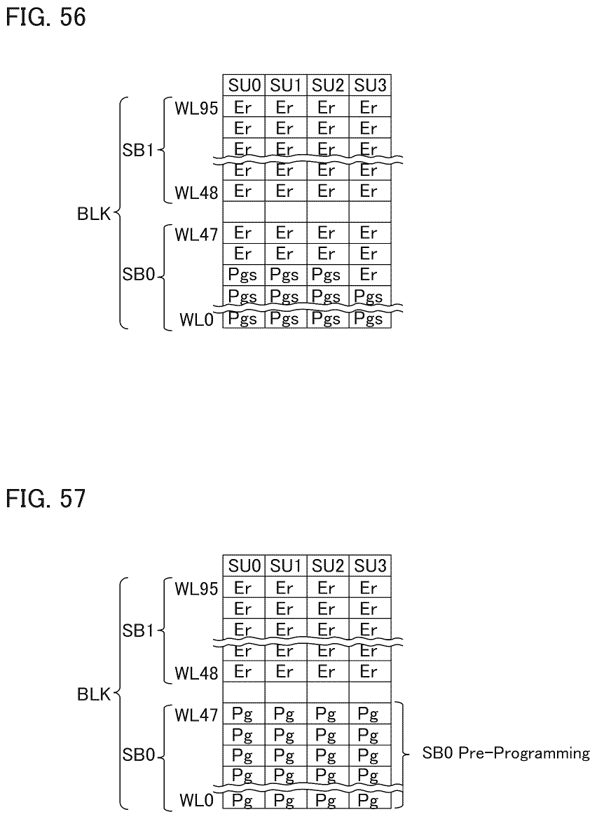

An operation when the sub-block SB1 is in the entire erase state and the sub-block SB0 is in the partial write state in the 1-bit mode (FIG. 56) is referred to as an operation example EX52. In the operation example EX52, the pre-programming is performed on the sub-block SB0 at Step S507, thereby turning all the pages PG (FIG. 54) in the sub-block SB0 to the write state Pg (FIG. 57). Next, the erase operation is performed on the sub-block SB0 at Step S508, thereby turning all the pages PG included in the memory block BLK to the erase state Er (FIG. 23).

An operation when the sub-blocks SB0, SB1 are in the entire write state in the 1-bit mode is referred to as an operation example EX53. In the operation example EX53, the block pre-programming is performed at Step S509, thereby turning all the pages PG included in the memory block BLK to the write state Pg. Next, the block erase operation is performed at Step S510, thereby turning all the pages PG included in the memory block BLK to the erase state Er (FIG. 23).

### Effects

In the 1-bit mode, when a random pattern writing is performed, approximately ½ of the memory cells MC are in the Er state in some cases. In such a case, when the erase operation is performed without performing the pre-programming, the over erase state of the memory cell MC occurs at a high rate. Therefore, in the 1-bit mode, by performing the block pre-programming on the entire memory block BLK as performed at Step S509, the occurrence of the over erase state of the memory cell MC can be suppressed.

In the 3-bit mode, when a random pattern writing is performed, approximately ⅛ of the memory cells MC are in the Er state in some cases. In such a case, the over erase state of the memory cell MC occurs at a relatively low rate. Therefore, in the 3-bit mode, the pre-programming is performed only on the unwritten page Pg as performed at Step S503. Accordingly, the occurrence of the write stress on the memory cell MC due to unnecessary pre-programming can be avoided.

### Modification of Fifth Embodiment

At Step S501, the determination by the controller does not need to be performed. The determination at Step S501 may be performed by, for example, the read operation performed by the memory die MD. In such a read operation, for example, information that is held in a part of the page PG written first in the memory block BLK and indicates whether the page PG is in the 1-bit mode or the 3-bit mode is read. Such information may be written on a part of the pages PG written at first in the memory block BLK at the write operation.

### OTHER EMBODIMENTS

The order of writing on the pages PG described in the first to the fifth embodiments can be variously changed. For example, the write operation of the page PG may be performed in descending order of n of the word line WL (n−1) and m of the word line WL (m−1), and in each of the word lines WL, the write operation does not need to be performed in the order of the string units SU0, SU1, SU2, and SU3.

### OTHERS

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a substrate;
a memory block including a first sub memory block and a second sub memory block arranged in a first direction intersecting with a surface of the substrate;
a bit line disposed on one side in the first direction with respect to the memory block;
a source line disposed on the other side in the first direction with respect to the memory block; and
a control circuit that controls the memory block, wherein
the first sub memory block includes:
a first memory cell electrically connected to the bit line and the source line; and
a first word line electrically connected to the first memory cell,
the second sub memory block includes:
a second memory cell electrically connected to the bit line and the source line; and
a second word line electrically connected to the second memory cell,
the control circuit is configured to be able to perform, in an erase operation on the memory block:
a first determination operation to determine whether or not the second memory cell is in a write state;
a first erase operation performed when the second memory cell is in the write state; and
a second erase operation performed when the second memory cell is in an erase state,
in the first erase operation:
an erase voltage is applied to one or both of the bit line and the source line; and
a select erase voltage lower than the erase voltage is applied to the first word line and the second word line, and
in the second erase operation:
the erase voltage is applied to one or both of the bit line and the source line;
the select erase voltage is applied to the first word line; and
an unselect erase voltage lower than the erase voltage and higher than the select erase voltage is applied to the second word line.

2. The semiconductor memory device according to claim 1, wherein
the control circuit is configured to be able to perform a pre-erase read operation on the second memory cell in the first determination operation, and
in the pre-erase read operation:
a read voltage is applied to the second word line; and
an unselect read voltage higher than the read voltage is applied to the first word line.

3. The semiconductor memory device according to claim 1, wherein
the control circuit is configured to be able to refer to a storage region in the control circuit in the first determination operation, and
the storage region holds information on a write status of the second sub memory block.

4. The semiconductor memory device according to claim 1, wherein
the control circuit is configured to be able to transmit:
a command set instructing the first erase operation; and
a command set instructing the second erase operation.

5. The semiconductor memory device according to claim 1, wherein
the control circuit is configured to be able to perform a write operation, and
when the first memory cell and the second memory cell are in the erase state, the write operation on the first memory cell is performed before the write operation on the second memory cell.

6. The semiconductor memory device according to claim 1, wherein
the control circuit is configured to be able to perform a write operation,
the second sub memory block includes a plurality of pages as a unit of the write operation, and
the second memory cell is included in a page on which the write operation is performed first among the plurality of pages.

7. The semiconductor memory device according to claim 1, wherein
the first sub memory block includes:
a plurality of first conductive layers arranged in the first direction;
a first semiconductor portion extending in the first direction and opposed to the plurality of first conductive layers; and
a first electric charge accumulating film disposed between the plurality of first conductive layers and the first semiconductor portion,
the second sub memory block includes:
a plurality of second conductive layers arranged in the first direction;
a second semiconductor portion extending in the first direction, opposed to the plurality of second conductive layers, and electrically connected to the first semiconductor portion; and
a second electric charge accumulating film disposed between the plurality of second conductive layers and the second semiconductor portion,
one of the plurality of first conductive layers functions as the first word line, and
one of the plurality of second conductive layers functions as the second word line.

8. The semiconductor memory device according to claim 7, further comprising
a semiconductor layer extending in the first direction, wherein
the semiconductor layer includes:
the first semiconductor portion;
the second semiconductor portion; and
a third semiconductor portion disposed between the first sub memory block and the second sub memory block, and connected to the first semiconductor portion and the second semiconductor portion, and
when:
a width in a second direction intersecting with the first direction of an end portion of the first semiconductor portion on a third semiconductor portion side is defined as a first width;
a width in the second direction of an end portion of the second semiconductor portion on the third semiconductor portion side is defined as a second width; and
a width in the second direction of the third semiconductor portion is defined as a third width,
the third width is larger than the first width and the second width.

9. A semiconductor memory device comprising:
a substrate;
a memory block including a first sub memory block and a second sub memory block arranged in a first direction intersecting with a surface of the substrate;
a bit line disposed on one side in the first direction with respect to the memory block;
a source line disposed on the other side in the first direction with respect to the memory block; and
a control circuit that controls the memory block, wherein
the first sub memory block includes:
a plurality of first memory cells electrically connected to the bit line and the source line; and
a plurality of first word lines electrically connected to the plurality of first memory cells,
the second sub memory block includes:
a plurality of second memory cells electrically connected to the bit line and the source line; and
a plurality of second word lines electrically connected to the plurality of second memory cells,
the control circuit is configured to be able to perform, in an erase operation on the memory block:
a first determination operation to determine whether or not at least one of the plurality of second memory cells is in a write state;
a second determination operation to determine whether or not at least one of the plurality of second memory cells is in an erase state;
a third determination operation to determine whether or not at least one of the plurality of first memory cells is in the erase state;
a first pre-erase write operation performed when at least one of the plurality of second memory cells is in the write state and at least one of the plurality of second memory cells is in the erase state; and
a second pre-erase write operation performed when at least one of the plurality of first memory cells is in the write state and at least one of the plurality of first memory cells is in the erase state,
in the first pre-erase write operation:
a program voltage is applied to the plurality of second word lines; and
an unselect write voltage lower than the program voltage is applied to the plurality of first word lines, and
in the second pre-erase write operation:
the program voltage is applied to the plurality of first word lines; and
the unselect write voltage is applied to the plurality of second word lines.

10. The semiconductor memory device according to claim 9, wherein
the control circuit is configured to be able to perform, in the erase operation on the memory block:
a first erase operation performed after the first pre-erase write operation; and
a second erase operation performed after the second pre-erase write operation,
in the first erase operation:
an erase voltage is applied to one or both of the bit line and the source line; and
a select erase voltage lower than the erase voltage is applied to the plurality of first word lines and the plurality of second word lines, and
in the second erase operation:
the erase voltage is applied to one or both of the bit line and the source line;
the select erase voltage is applied to the plurality of first word lines; and
an unselect erase voltage lower than the erase voltage and higher than the select erase voltage is applied to the plurality of second word lines.

11. The semiconductor memory device according to claim 9, wherein
the control circuit is configured to be able to perform a pre-erase read operation on at least one of the plurality of second memory cells in the first determination operation and the second determination operation, and
in the pre-erase read operation:
a read voltage is applied to at least one of the plurality of second word lines; and
an unselect read voltage higher than the read voltage is applied to the plurality of first word lines.

12. The semiconductor memory device according to claim 9, wherein
the control circuit is configured to be able to perform a pre-erase read operation on at least one of the plurality of first memory cells in the third determination operation, and
in the pre-erase read operation:
a read voltage is applied to at least one of the plurality of first word lines; and
an unselect read voltage higher than the read voltage is applied to the plurality of second word lines.

13. The semiconductor memory device according to claim 9, wherein
the control circuit is configured to be able to refer to a storage region in the control circuit in the first determination operation, the second determination operation, and the third determination operation, and
the storage region holds information on a write status of the first sub memory block and the second sub memory block.

14. The semiconductor memory device according to claim 10, wherein
the control circuit is configured to be able to transmit:
a command set instructing the first pre-erase write operation;
a command set instructing the second pre-erase write operation;
a command set instructing the first erase operation; and
a command set instructing the second erase operation.

15. The semiconductor memory device according to claim 9, wherein
the control circuit is configured to be able to perform a write operation, and
when the plurality of first memory cells and the plurality of second memory cells are in the erase state, the write operation on the plurality of first memory cells is performed before the write operation on the plurality of second memory cells.

16. The semiconductor memory device according to claim 9, wherein
the first sub memory block includes:
a plurality of first conductive layers arranged in the first direction;
a first semiconductor portion extending in the first direction and opposed to the plurality of first conductive layers; and
a first electric charge accumulating film disposed between the plurality of first conductive layers and the first semiconductor portion,
the second sub memory block includes:
a plurality of second conductive layers arranged in the first direction;
a second semiconductor portion extending in the first direction, opposed to the plurality of second conductive layers, and electrically connected to the first semiconductor portion; and
a second electric charge accumulating film disposed between the plurality of second conductive layers and the second semiconductor portion,
the plurality of first conductive layers function as the plurality of first word lines, and
the plurality of second conductive layers function as the plurality of second word lines.

17. The semiconductor memory device according to claim 16, comprising
a semiconductor layer extending in the first direction, wherein
the semiconductor layer includes:
the first semiconductor portion;
the second semiconductor portion; and
a third semiconductor portion disposed between the first sub memory block and the second sub memory block, and connected to the first semiconductor portion and the second semiconductor portion, and
when:
a width in a second direction intersecting with the first direction of an end portion of the first semiconductor portion on a third semiconductor portion side is defined as a first width;
a width in the second direction of an end portion of the second semiconductor portion on the third semiconductor portion side is defined as a second width; and
a width in the second direction of the third semiconductor portion is defined as a third width,
the third width is larger than the first width and the second width.
